(19) United States
(12) Patent Application Publication
(10) Pub. No.: US 2026/0026209 A1
(43) Pub. Date: Jan. 22, 2026

(54) DISPLAY DEVICE AND A METHOD FOR MANUFACTURING THE SAME, AND AN ELECTRONIC DEVICE FOR PROVIDING AN IMAGE

(71) Applicant: SAMSUNG DISPLAY CO., LTD., YONGIN-SI (KR)

(72) Inventors: Keun Young PARK, Yongin-si (KR); Seung Jun YU, Yongin-si (KR); Sa Rah LEE, Yongin-si (KR)

(21) Appl. No.: 19/078,449

(22) Filed: Mar. 13, 2025

(30) Foreign Application Priority Data
Jul. 18, 2024 (KR) 10-2024-0095275
Oct. 10, 2024 (KR) 10-2024-0137278

(51) Int. Cl. H10K 59/124; H10K 59/12; H10K 59/121; H10K 102/00

(52) U.S. Cl. CPC H10K 59/124; H10K 59/1201; H10K 59/1213; H10K 2102/351

(57) ABSTRACT

A display device including: a substrate; a circuit layer disposed on the substrate and including a transistor and insulating layers; and a light-emitting element layer disposed on the circuit layer and including a light-emitting element electrically connected to the transistor, wherein the circuit layer includes: a contact hole penetrating at least two of the insulating layers; and a conductive pattern covering a side surface and bottom surface of the contact hole, extending upwardly beyond a top of the contact hole, and including at least two protrusions that extend toward a central axis of the contact hole in a cross-sectional view.

### CROSS-REFERENCE TO RELATED APPLICATIONS

This application claims priority under 35 U.S.C. § 119 to Korean Patent Application No. 10-2024-0095275 filed on Jul. 18, 2024, and Korean Patent Application No. 10-2024-0137278 filed on Oct. 10, 2024, in the Korean Intellectual Property Office, the disclosures of which are incorporated by reference herein in their entireties.

### 1. Technical Field

The present disclosure relates to a display device and a method for manufacturing the same, and an electronic device for providing an image.

### 2. Description of the Related Art

With the advancement of the information society, the demand for display devices for displaying images has grown significantly. In response, display devices are being developed in diverse forms and sizes to meet these needs.

### SUMMARY

Embodiments of the present disclosure provide a display device and a method for manufacturing the same that can prevent poor contact in contact holes, and improve reliability. Embodiments of the present disclosure also provide an electronic device that provides an image.

According to an embodiment of the present disclosure, there is provided a display device including: a substrate; a circuit layer disposed on the substrate and including a transistor and insulating layers; and a light-emitting element layer disposed on the circuit layer and including a light-emitting element electrically connected to the transistor, wherein the circuit layer includes: a contact hole penetrating at least two of the insulating layers; and a conductive pattern covering a side surface and bottom surface of the contact hole, extending upwardly beyond a top of the contact hole, and including at least two protrusions that extend toward a central axis of the contact hole in a cross-sectional view.

The protrusions include: a first protrusion disposed at a height less than or equal to the top of the contact hole; and a second protrusion disposed at a height greater than that of the first protrusion.

A thickness of the second protrusion is greater than a thickness of the first protrusion, measured along the side surface of the contact hole.

An upper end of the conductive pattern, including the second protrusion, completely covers an entrance of the contact hole.

The conductive pattern includes an undercut-shaped recess disposed between the first and second protrusions.

The conductive pattern includes a third protrusion extending toward the central axis of the contact hole in a cross-sectional view, and the first and second protrusions are disposed at a height less than or equal to the top of the contact hole.

The conductive pattern fills only a portion of the contact hole.

The contact hole includes a void surrounded by the conductive pattern.

The display device further includes: an organic layer disposed inside the contact hole and filling a space surrounded by the conductive pattern.

An aspect ratio of the contact hole is 0.3 or greater, and the conductive pattern has a thickness on the bottom surface of the contact hole that is at least 15% of a thickness at an upper portion of the conductive pattern around the contact hole.

An aspect ratio of the contact hole is 0.6 or greater, and the conductive pattern has a thickness on the bottom surface of the contact hole that is at least 50% of a thickness at an upper portion of the conductive pattern around the contact hole.

The contact hole includes: a lower contact hole penetrating portions of the at least two insulating layers; and an upper contact hole disposed on the lower contact hole and penetrating other portions of the at least two insulating layers, and the conductive pattern includes: a lower conductive pattern covering a side surface and bottom surface of the lower contact hole and extending upwardly beyond a top of the lower contact hole; and an upper conductive pattern disposed on the lower conductive pattern, covering a side surface and bottom surface of the upper contact hole, and extending upwardly beyond a top of the upper contact hole.

At least one of the lower and upper conductive patterns includes at least two protrusions extending toward a central axis of the lower or upper contact hole in a cross-sectional view.

The at least two insulating layers are disposed on an active layer of the transistor, the contact hole penetrates the at least two insulating layers to expose a portion of the active layer, and the conductive pattern is electrically connected to the exposed portion of the active layer.

According to an embodiment of the present disclosure, there is provided a method of manufacturing a display device including: forming a pattern of a semiconductor layer or a conductive layer on a substrate covering the pattern with insulating layers; forming a contact hole that penetrates the insulating layers to expose a portion of the pattern; and forming a conductive pattern that fills at least a portion of the contact hole, wherein the forming the conductive pattern includes: forming a first conductive film on the insulating layers and the contact hole; forming a first organic film on the first conductive film; retaining only a portion of the first organic film inside the contact hole and removing other portions of the first organic film; etching the first conductive film using a remaining portion of the first organic film as a mask; removing the remaining portion of the first organic film; and forming a second conductive film on the insulating layers and the first conductive film.

The forming the first conductive film and the forming the second conductive film include depositing a conductive material over an entire surface, which includes the insulating layers and the contact hole, by sputtering.

The forming the conductive pattern includes: forming a second organic film on a portion of the second conductive film inside the contact hole; etching the second conductive film using the second organic film as a mask; forming a third conductive film on the insulating layers and the second conductive film; and etching the third conductive film into a shape corresponding to the conductive pattern.

The forming the conductive pattern further includes removing the second organic film before the forming the third conductive film.

Before the forming the third conductive film, the second organic film is not removed, or a separate organic layer is formed on the second conductive film and the third conductive film is formed on the second organic film or the organic layer.

The forming the conductive pattern further includes etching the second conductive film into a shape corresponding to the conductive pattern.

According to an embodiment of the present disclosure, there is provided an electronic device for providing an image including: a processor; a memory having stored application programs for execution by the processor; a display device including: a substrate; a circuit layer disposed on the substrate and including a transistor and insulating layers; and a light-emitting element layer disposed on the circuit layer and including a light-emitting element electrically connected to the transistor, wherein the circuit layer includes: a contact hole passing through at least two of the insulating layers; and a conductive pattern covering a side surface and bottom surface of the contact hole, extending upwardly beyond a top of the contact hole, and including at least two protrusions that extend toward a central axis of the contact hole in a cross-sectional view.

According to the embodiments, a conductive pattern can be effectively formed inside a contact hole, thereby preventing poor contact and enhancing the reliability of the display device.

According to the embodiments, even in high-resolution display devices with narrow and deep contact holes, the contact hole can be effectively filled with a conductive pattern of appropriate thickness and shape. This enables the optimization of the high-resolution display device's design while enhancing its reliability.

It should be noted that the effects of the present disclosure are not limited to those described above; additional effects will become apparent from the following description.

### BRIEF DESCRIPTION OF THE DRAWINGS

The above and other features of the present disclosure will become more apparent by describing in detail embodiments thereof with reference to the attached drawings, in which:

FIG. 1 is a perspective view illustrating a display device according to an embodiment;

FIG. 2 is an equivalent circuit diagram illustrating a pixel according to an embodiment;

FIG. 3 is a cross-sectional view illustrating a display device according to an embodiment;

FIG. 4 is a cross-sectional view illustrating a conductive pattern according to an embodiment;

FIG. 5 is a cross-sectional view illustrating a conductive pattern according to an embodiment;

FIG. 6 is a cross-sectional view illustrating a conductive pattern according to an embodiment;

FIG. 7 is a cross-sectional view illustrating a conductive pattern according to an embodiment;

FIGS. 8, 9, 10, 11, 12, 13, 14, 15, 16, 17, 18, 19 and 20 are cross-sectional views illustrating a method for manufacturing a display device according to an embodiment;

FIGS. 21, 22 and 23 are cross-sectional views illustrating a method for manufacturing a display device according to an embodiment;

FIG. 24 is a perspective view illustrating a head-mounted display (HMD) device according to an embodiment;

FIG. 25 is an exploded perspective view illustrating the HMD device of FIG. 24;

FIG. 26 is a perspective view illustrating an HMD device according to another embodiment; and

FIG. 27 is an electronic device in which embodiments of the present disclosure are implemented.

### DETAILED DESCRIPTION OF THE EMBODIMENTS

The present disclosure will now be described more fully hereinafter with reference to the accompanying drawings, in which embodiments thereof are shown. This disclosure may, however, be embodied in different forms and should not be construed as limited to the embodiments set forth herein.

It will be understood that when an element or a layer is referred to as being “on” another element or layer, it can be directly on the other element or layer, or intervening layers may also be present. The same reference numbers may indicate the same components throughout the specification.

It will be understood that, although the terms “first,” “second,” etc. may be used herein to describe various elements, these elements should not be limited by these terms. These terms are used to distinguish one element from another element. For instance, a first element discussed below could be termed a second element. Similarly, the second element could also be termed the first element.

Features of various embodiments of the present disclosure may be partially or fully combined and may interact technically in various ways. Each embodiment may be implemented independently or in combination with others.

The present disclosure relates to a display device and its manufacturing method, enhancing reliability by addressing poor electrical contact issues in the circuit layer's contact holes. The device includes a substrate, a circuit layer with transistors and insulating layers, and a light-emitting element layer. Unique conductive patterns in the contact holes, featuring protrusions at varying heights and thicknesses, ensure robust electrical connections even in high-resolution displays with narrow, deep contact holes, minimizing defects and optimizing performance.

The manufacturing method refines these conductive patterns through sequential deposition and etching, ensuring even material distribution and preventing blockages. Versatile and adaptable, the device suits applications in portable electronics, televisions, and VR systems while supporting various light-emitting technologies like OLEDs and quantum dots.

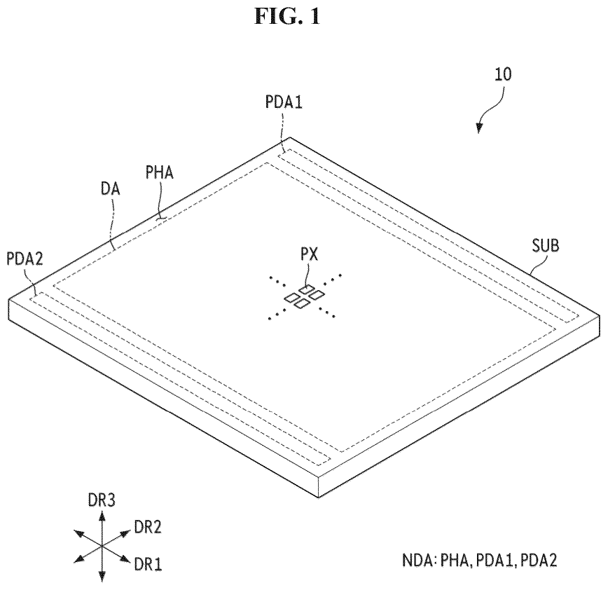

FIG. 1 is a perspective view illustrating a display device according to an embodiment.

Referring to FIG. 1, a display device 10 is a device for displaying moving or still images and may be used as a display screen in various electronic devices. For example, the display device 10 may be used as the display screen in portable electronic devices such as mobile phones, smartphones, tablet personal computers (PCs), smartwatches, watch phones, mobile communication terminals, electronic notebooks, e-book readers, portable multimedia players (PMPs), navigation systems, ultra mobile PCs (UMPCs), and other similar devices. In addition, the display device 10 may also be included in other electronic devices, such as televisions, laptops, monitors, billboards, Internet of Things (IOT) devices, and similar electronic devices, serving as their display screen. Furthermore, the display device 10 may be included in other electronic devices, such as virtual reality (VR) or augmented reality (AR) devices.

In one embodiment, the display device 10 may be a light-emitting display device that includes light-emitting elements. For example, the display device 10 may be an organic light-emitting display device that includes organic light-emitting diodes (OLEDs), a quantum dot light-emitting display device that includes a quantum dot light-emitting layer, an inorganic light-emitting display device that includes an inorganic semiconductor, or a micro or nano light-emitting diode display device that includes micro or nano light-emitting diodes (micro LEDs or nano LEDs). However, the present disclosure is not limited to this. For example, the display device 10 may include other types of display devices in addition to light-emitting display devices.

Embodiments where the display device 10 is an organic light-emitting display device will hereinafter be described. However, the display device 10 is not limited to an organic light-emitting display device, and the technical features of the embodiments to be described later may also be applicable to other types of display devices.

The display device 10 may include a substrate SUB and pixels PX arranged on the substrate SUB.

The substrate SUB may be a base layer for manufacturing or providing the display device 10. The substrate SUB may have a rectangular planar shape on a plane defined by a first direction DR1 and a second direction DR2, but the present disclosure is not limited thereto. For example, the substrate SUB may also have other planar shapes, such as a polygonal, circular, elliptical, or irregular shape.

In FIG. 1, the first direction DR1 may indicate the horizontal direction (or vertical direction) of the substrate SUB (or the display device 10), and the second direction DR2 may indicate the vertical direction (or horizontal direction) of the substrate SUB. A third direction DR3 may indicate the thickness direction or height direction of the substrate SUB.

The substrate SUB and the display device 10 that includes the substrate SUB may include a display area DA and a non-display area NDA. The display area DA refers to the region where images are displayed, while the non-display area NDA encompasses the remaining region outside the display area DA.

The display area DA may be an area where the pixels PX are arranged. For example, the display area DA may include the pixels PX and wiring (or portions of the wiring) connected to the pixels PX. Here, the term “connected” or “connection” may include both electrical connections and/or physical connections.

The non-display area NDA may be arranged around the display area DA. In one embodiment, the non-display area NDA may include a first pad area PDA1, a second pad area PDA2, and a peripheral area PHA. The non-display area NDA may include wiring connected to the pixels PX such as portions of the wiring extending from the display area DA into the non-display area NDA, as well as pads. In one embodiment, the non-display area NDA may further include a driving circuit area where at least portions of driving circuitry connected to the pixels PX are located.

In FIG. 1, the display device 10 is illustrated as including the first and second pad areas PDA1 and PDA2 on different sides (for example, the upper and lower sides) of the display area DA. However, the number and location of the first and second pad areas PDA1 and PDA2 is not particularly limited. For example, the display device 10 may include only one of the first and second pad areas PDA1 and PDA2, or may include three or more pad areas.

The first and second pad areas PDA1 and PDA2 may each include pads connected to an external circuit board. These pads enable the supply of driving signals and driving voltages from the circuit board to the display device 10 for operating the pixels PX.

The peripheral area PHA may refer to the portion of the non-display area NDA that excludes the first and second pad areas PDA1 and PDA2. The peripheral area PHA may surround the display area DA. The peripheral area PHA may or may not include the driving circuit area.

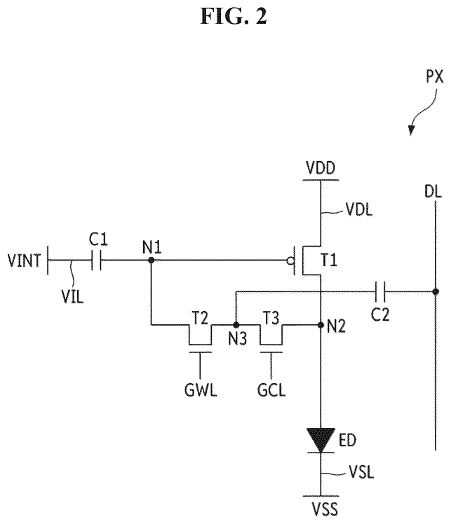

FIG. 2 is an equivalent circuit diagram illustrating a pixel according to an embodiment.

Referring to FIG. 2, a pixel PX may be connected to signal lines including a first scan line GWL, a second scan line GCL, and a data line DL, and to power lines including a first voltage line VDL, a second voltage line VSL, and an initialization voltage line (or an initialization signal line) VIL. The types and numbers of signal lines and power lines connected to the pixel PX may vary based on the type or structure of the pixel PX.

The first scan line GWL and the second scan line GCL may be connected between a scan driving circuit and the pixel PX. The first scan line GWL transmits a first scan signal output from the scan driving circuit to the pixel PX. In one embodiment, the first scan line GWL may be a write scan line, and the first scan signal may be a write scan signal. The second scan line GCL transmits a second scan signal output from the scan driving circuit to the pixel PX. In one embodiment, the second scan line GCL may be a control scan line, and the second scan signal may be a control scan signal. The scan driving circuit may be disposed on the substrate SUB, or on a circuit board connected to the display device 10 through signal pads (e.g., scan pads) arranged in at least one of the first pad area PDA1 or the second pad area PDA2.

The data line DL may be connected between a data driving circuit and the pixel PX. The data line DL transmits a data voltage output from the data driving circuit to the pixel PX. The data driving circuit may be disposed on the substrate SUB, or on a circuit board connected to the display device 10 through signal pads (e.g., data pads) arranged in at least one of the first pad area PDA1 or the second pad area PDA2.

The first voltage line VDL and the second voltage line VSL may be connected between a power supply circuit and the pixel PX. The first voltage line VDL and the second voltage line VSL transmit a first driving voltage VDD and a second driving voltage VSS output from the power supply circuit to the pixel PX. In one embodiment, the first driving voltage VDD may be a high-potential pixel voltage, and the second driving voltage VSS may be a low-potential pixel voltage. In one embodiment, the power supply circuit may be disposed on a circuit board connected to the display device 10 through power pads arranged in at least one of the first pad area PDA1 or the second pad area PDA2.

The initialization voltage line VIL may be connected between the power supply circuit or the scan driving circuit and the pixel PX. The initialization voltage line VIL transmits an initialization voltage VINT output from the power supply circuit or the scan driving circuit to the pixel PX.

The pixel PX may include a light-emitting element ED and a pixel circuit electrically connected to the light-emitting element ED.

The light-emitting element ED may be connected between the pixel circuit and the second voltage line VSL. For example, a first electrode (e.g., the anode) of the light-emitting element ED may be connected to the pixel circuit via a second node N2, and a second electrode (e.g., the cathode) of the light-emitting element ED may be connected to the second voltage line VSL.

The light-emitting element ED functions as the light source of the pixel PX and emits light in response to a driving current supplied from the pixel circuit. In one embodiment, the light-emitting element ED may be an OLED, but the present disclosure is not limited thereto. Alternatively, for example, the light-emitting element ED may be an inorganic light-emitting element, a quantum dot light-emitting element, or another type of light-emitting element.

The pixel circuit may be connected between the first voltage line VDL and the light-emitting element ED. In addition, the pixel circuit may also be connected to the first scan line GWL, the second scan line GCL, the data line DL, and the initialization voltage line VIL.

The pixel circuit may include circuit elements such as transistors and capacitors. The pixel circuit may be configured to enable the pixel PX to emit light with uniform brightness corresponding to a grayscale data voltage and may therefore include multiple transistors and at least one capacitor. In one embodiment, the pixel circuit may include first, second, and third transistors T1, T2, and T3 and first and second capacitors C1 and C2. The type and structure of the pixel circuit may vary depending on the embodiment.

In one embodiment, the pixel circuit may include P-type transistors and N-type transistors. For example, the first transistor T1 may be a P-type transistor, and the second transistor T2 and the third transistor T3 may be N-type transistors. In one embodiment, P- and N-type transistors may include active layers formed from different materials. For example, the active layer of a P-type transistor may include polysilicon, and the active layer of an N-type transistor may include an oxide semiconductor.

However, the present disclosure is not limited to this. Alternatively, for example, the first, second, and third transistors T1, T2, and T3 may be transistors of the same type (e.g., all P- or N-type transistors).

The first, second, and third transistors T1, T2, and T3 may each include a gate electrode, a source electrode (or a source region functioning as the source electrode), and a drain electrode (or a drain region functioning as the drain electrode). The source electrodes and drain electrodes of the first, second, and third transistors T1, T2, and T3 may be first electrodes and second electrodes. Depending on the voltage applied to the two terminals of each of the first, second, and third transistors T1, T2, and T3, and the type of the corresponding transistor (e.g., P-type or N-type), one of the first and second electrodes may function as the source electrode, and the other may function as the drain electrode.

The gate electrode of the first transistor T1 may be connected to a first node N1, the source electrode of the first transistor T1 may be connected to the first voltage line VDL, and the drain electrode of the first transistor T1 may be connected to the second node N2. The second node N2 may be the node to which the first electrode (e.g., the anode) of the light-emitting element ED is connected. The first transistor T1 may control the driving current flowing to the light-emitting element ED according to the voltage at the first node N1.

The gate electrode of the second transistor T2 may be connected to the first scan line GWL, the source electrode of the second transistor T2 may be connected to the first node N1, and the drain electrode of the second transistor T2 may be connected to a third node N3. The second transistor T2 may be turned on by the first scan signal, which is a gate-on voltage applied to the first scan line GWL, thereby electrically connecting the first node N1 and the third node N3.

The first node N1 may be connected to the first electrode of the first capacitor C1. The voltage at the first node N1 may be initialized by the initialization voltage VINT applied to the initialization voltage line VIL, which is connected to the second electrode of the first capacitor C1.

The third node N3 may be connected to the first electrode of the second capacitor C2. The voltage at the third node N3 may change to a voltage corresponding to the data voltage applied to the data line DL, which is connected to the second electrode of the second capacitor C2.

The gate electrode of the third transistor T3 may be connected to the second scan line GCL, the source electrode of the third transistor T3 may be connected to the third node N3, and the drain electrode of the third transistor T3 may be connected to the second node N2. The third transistor T3 may be turned on by the second scan signal, which is a gate-on voltage applied to the second scan line GCL, thereby electrically connecting the third node N3 and the second node N2.

The first capacitor C1 may be connected between the first node N1 and the initialization voltage line VIL. For example, the first electrode of the first capacitor C1 may be connected to the first node N1, and the second electrode of the first capacitor C1 may be connected to the initialization voltage line VIL, thereby maintaining the potential difference between the first node N1 and the initialization voltage line VIL. The voltage at the first node N1 may be initialized by the initialization voltage VINT applied to the initialization voltage line VIL.

The second capacitor C2 may be connected between the third node N3 and the data line DL. For example, the first electrode of the second capacitor C2 may be connected to the third node N3, and the second electrode of the second capacitor C2 may be connected to the data line DL, thereby maintaining the potential difference between the third node N3 and the data line DL. The voltage at the third node N3 may change to a voltage corresponding to the data voltage applied to the data line DL.

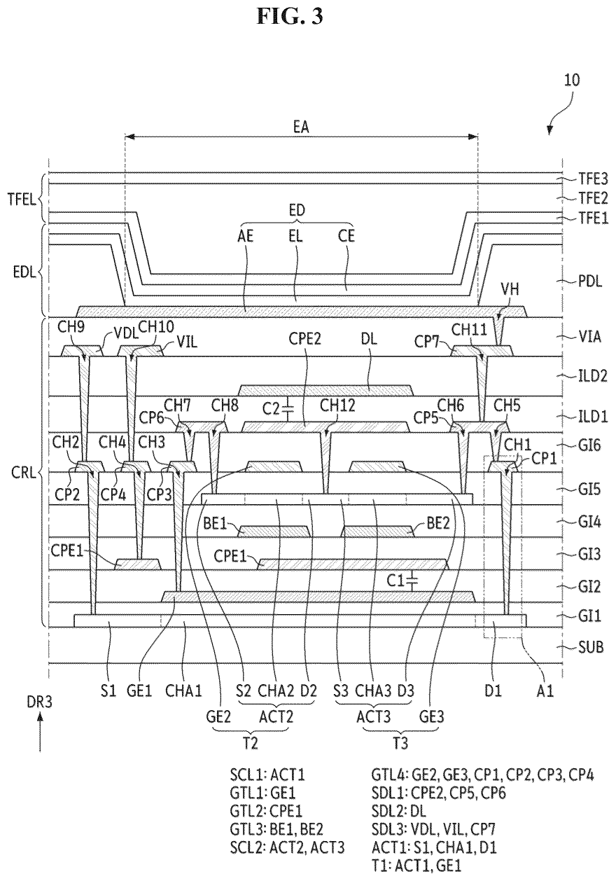

FIG. 3 is a cross-sectional view illustrating the display device according to an embodiment. For example, FIG. 3 illustrates a schematic cross-section of a portion of the display device 10 (e.g., one pixel region located in the display area DA) where a pixel PX is arranged.

Referring to FIG. 3, the display device 10 may include a substrate SUB and a circuit layer CRL arranged on the substrate SUB. In one embodiment, the display device 10 may be a light-emitting display device that includes a light-emitting element ED, and may further include a light-emitting element layer EDL and an encapsulation layer TFEL. In one embodiment, the circuit layer CRL, the light-emitting element layer EDL, and the encapsulation layer TFEL may be sequentially disposed on the substrate SUB along the third direction DR3.

FIG. 3 illustrates a structure where a first transistor T1 of the circuit layer CRL is directly disposed on the substrate SUB, but the present disclosure is not limited thereto. Alternatively, for example, a buffer layer (or barrier layer) may be formed on the substrate SUB, and the circuit layer CRL may be disposed on the buffer layer.

The substrate SUB may be a base layer for forming the display device 10. For example, the substrate SUB may serve as a support for a display panel that includes the pixel PX.

The substrate SUB may be a substrate that includes an insulating material such as glass and has rigid characteristics, but the present disclosure is not limited thereto. For example, the substrate SUB may include an insulating material such as a polymer resin and may be a flexible substrate capable of bending, folding, or rolling. In another example, the substrate SUB may be a semiconductor substrate, and the substrate SUB and the pixel circuit of the pixel PX may be formed as a semiconductor circuit substrate that includes a complementary metal-oxide semiconductor (CMOS) circuit formed using semiconductor processing.

The circuit layer CRL may be disposed on the substrate SUB (or on the buffer layer). The circuit layer CRL may include circuit elements included in the pixel PX (e.g., circuit elements included in the pixel circuit) and wiring connected to the pixel PX. For example, the circuit layer CRL may include first, second, and third transistors T1, T2, and T3, first and second capacitors C1 and C2, a first scan line GWL, a second scan line GCL, a data line DL, a first voltage line VDL, a second voltage line VSL, and an initialization voltage line VIL, as illustrated in FIG. 2.

The circuit layer CRL may include at least one semiconductor layer, a plurality of conductive layers, and a plurality of insulating layers disposed on the substrate SUB (or on the buffer layer). The semiconductor layer of the circuit layer CRL may include the active layers of the transistors disposed within the circuit layer CRL. The conductive layers of the circuit layer CRL may include conductive patterns included in or connected to the circuit elements (e.g., transistors and capacitors) disposed within the circuit layer CRL. These conductive patterns may include the electrodes of the circuit elements, connection patterns connected to the circuit elements, and/or wiring. The insulating layers of the circuit layer CRL may be disposed between the semiconductor layer and the conductive layers.

In one embodiment, the pixel PX may include at least two types of transistors, and the circuit layer CRL may include a plurality of semiconductor layers. For example, the circuit layer CRL may include a first semiconductor layer SCL1 that includes a first active layer ACT1 of the first transistor T1 and a second semiconductor layer SCL2 that includes a second active layer ACT2 of the second transistor T2 and a third active layer ACT3 of the third transistor T3. The first semiconductor layer SCL1 and the second semiconductor layer SCL2 may be disposed on different layers on the substrate SUB. Therefore, the integration level of the circuit layer CRL can be enhanced, enabling the design of the circuit layer CRL to be optimized. For example, in a high-resolution display device with smaller-sized pixels PX, the circuit elements of the pixels PX may be efficiently arranged within the constrained pixel regions.

In one embodiment, the conductive layers of the circuit layer CRL may include a first conductive layer GTL1, a second conductive layer GTL2, a third conductive layer GTL3, a fourth conductive layer GTL4, a fifth conductive layer SDL1, a sixth conductive layer SDL2, and a seventh conductive layer SDL3. The first conductive layer GTL1, the second conductive layer GTL2, the third conductive layer GTL3, the fourth conductive layer GTL4, the fifth conductive layer SDL1, the sixth conductive layer SDL2, and the seventh conductive layer SDL3 may correspond to a first gate conductive layer, a second gate conductive layer, a third gate conductive layer, a fourth gate conductive layer, a first source-drain conductive layer (or first data conductive layer), a second source-drain conductive layer (or second data conductive layer), and a third source-drain conductive layer (or third data conductive layer), respectively, but the present disclosure is not limited thereto.

In one embodiment, the insulating layers of the circuit layer CRL may include a first insulating layer GI1, a second insulating layer GI2, a third insulating layer GI3, a fourth insulating layer GI4, a fifth insulating layer GI5, a sixth insulating layer GI6, a seventh insulating layer ILD1, an eighth insulating layer ILD2, and a ninth insulating layer VIA, which are sequentially disposed on the substrate SUB along the third direction DR3. The first insulating layer GI1, the second insulating layer GI2, the third insulating layer GI3, the fourth insulating layer GI4, the fifth insulating layer GI5, the sixth insulating layer GI6, the seventh insulating layer ILD1, the eighth insulating layer ILD2, and the ninth insulating layer VIA may correspond to a first gate insulating layer, a second gate insulating layer, a third gate insulating layer, a fourth gate insulating layer, a fifth gate insulating layer, a sixth gate insulating layer, a first interlayer insulating layer, a second interlayer insulating layer, and a planarization layer (or via layer), respectively, but the present disclosure is not limited thereto.

The structure of the circuit layer CRL may vary depending on the embodiment. For example, the number, type, and/or location of the semiconductor layers, conductive layers, and insulating layers included in the circuit layer CRL, as well as the number, type, and/or shape of the patterns within these layers, can be adjusted based on the design structure of the pixel circuit and wiring.

The first semiconductor layer SCL1 may be disposed on the substrate SUB (or the buffer layer). The first semiconductor layer SCL1 may include semiconductor patterns that contain a semiconductor material (e.g., polysilicon, amorphous silicon, oxide semiconductor, or other semiconductor materials). In one embodiment, the semiconductor patterns of the first semiconductor layer SCL1 may include polysilicon. In one embodiment, the first semiconductor layer SCL1 may include the first active layer ACT1 of the first transistor T1 of the pixel PX.

The first active layer ACT1 may include a first channel region CHA1, a first source region S1, and a first drain region D1. The first channel region CHA1 may overlap with a first gate electrode GE1 of the first transistor T1. The first channel region CHA1 may form a channel in response to the voltage applied to the first gate electrode GE1. The first source region S1 and the first drain region D1 may be disposed on both sides of the first channel region CHA1. The first source region S1 and the first drain region D1 may have higher conductivity compared to the first channel region CHA1. For example, the carrier concentration of the first source region S1 and the first drain region D1 may be higher than the carrier concentration of the first channel region CHA1.

In one embodiment, the first source region S1 may be electrically connected to the first voltage line VDL through a second conductive pattern CP2 (or the first source electrode of the first transistor T1). The second conductive pattern CP2 may pass through several insulating layers. The first drain region D1 may be electrically connected to a first electrode AE of a light-emitting element ED and the third drain region D3 of the third transistor T3 through at least one conductive pattern, including a first conductive pattern CP1 (or the first drain electrode of the first transistor T1). The first conductive pattern CP1 may pass through several insulating layers.

The first insulating layer GI1 may be disposed on the substrate SUB and the first semiconductor layer SCL1 and may cover the semiconductor patterns of the first semiconductor layer SCL1. For example, the first insulating layer GI1 may cover the first active layer ACT1.

The first conductive layer GTL1 may be disposed on the first insulating layer GI1. The first conductive layer GTL1 may include conductive patterns that contain a conductive material. For example, the first conductive layer GTL1 may include the first gate electrode GE1 of the first transistor T1 of the pixel PX. In one embodiment, the first gate electrode GE1 may be integrally formed with the first electrode of the first capacitor C1. For example, the first gate electrode GE1 may overlap with a first capacitor electrode CPE1, and the first capacitor C1 may be formed by the first gate electrode GE1 and the first capacitor electrode CPE1. The first gate electrode GE1 and the first capacitor electrode CPE1 may serve as the first and second electrodes, respectively, of the first capacitor C1.

The second insulating layer GI2 may be disposed on the first insulating layer GI1 and the first conductive layer GTL1 and may cover the conductive patterns of the first conductive layer GTL1. For example, the second insulating layer GI2 may cover the first gate electrode GE1.

The second conductive layer GTL2 may be disposed on the second insulating layer GI2. The second conductive layer GTL2 may include conductive patterns that contain a conductive material. For example, the second conductive layer GTL2 may include the first capacitor electrode CPE1, which overlaps with the first gate electrode GEI of the pixel PX. The first capacitor electrode CPE1, which is illustrated in FIG. 3 as two separate patterns, may be a single electrode when viewed in a plan view.

The third insulating layer GI3 may be disposed on the second insulating layer GI2 and the second conductive layer GTL2, and may cover the conductive patterns of the second conductive layer GTL2. For example, the third insulating layer GI3 may cover the first capacitor electrode CPE1.

The third conductive layer GTL3 may be disposed on the third insulating layer GI3. The third conductive layer GTL3 may include conductive patterns that contain a conductive material. For example, the third conductive layer GTL3 may include a first bottom electrode BE1 and a second bottom electrode BE2, which overlap with the second active layer ACT2 of the second transistor T2 of the pixel PX and the third active layer ACT3 of the third transistor T3 of the pixel PX. The first bottom electrode BE1 may overlap with the second channel region CHA2 of the second active layer ACT2, and the second bottom electrode BE2 may overlap with the third channel region CHA3 of the third active layer ACT3. In one embodiment, the first bottom electrode BE1 may be electrically connected to a second gate electrode GE2 of the second transistor T2, but the present disclosure is not limited thereto. In one embodiment, the second bottom electrode BE2 may be electrically connected to a third gate electrode GE3 of the third transistor T3, but the present disclosure is not limited thereto.

The fourth insulating layer GI4 may be disposed on the third insulating layer GI3 and the third conductive layer GTL3, and may cover the conductive patterns of the third conductive layer GTL3. For example, the fourth insulating layer GI4 may cover the first bottom electrode BE1 and the second bottom electrode BE2.

The second semiconductor layer SCL2 may be disposed on the fourth insulating layer GI4. The second semiconductor layer SCL2 may include semiconductor patterns that contain a semiconductor material (e.g., polysilicon, amorphous silicon, oxide semiconductor, or other semiconductor materials). In one embodiment, the semiconductor patterns of the second semiconductor layer SCL2 may include an oxide semiconductor. In one embodiment, the second semiconductor layer SCL2 may include the second active layer ACT2 and the third active layer ACT3 included in the second transistor T2 and the third transistor T3, respectively, of the pixel PX. In one embodiment, the second active layer ACT2 and the third active layer ACT3 may be formed as an integral structure. For example, the second drain region D2 and the third source region S3 may constitute a single continuous region.

The second active layer ACT2 may include a second channel region CHA2, a second source region S2, and a second drain region D2. The second channel region CHA2 may overlap with the second gate electrode GE2 of the second transistor T2. The second channel region CHA2 may form a channel in response to the voltage applied to the second gate electrode GE2. The second source region S2 and the second drain region D2 may be disposed on both sides of the second channel region CHA2. The second source region S2 and the second drain region D2 may have higher conductivity than the second channel region CHA2.

The third active layer ACT3 may include a third channel region CHA3, a third source region S3, and a third drain region D3. The third channel region CHA3 may overlap with the third gate electrode GE3 of the third transistor T3. The third channel region CHA3 may form a channel in response to the voltage applied to the third gate electrode GE3. The third source region S3 and the third drain region D3 may be disposed on both sides of the third channel region CHA3. The third source region S3 and the third drain region D3 may have higher conductivity than the third channel region CHA3.

In one embodiment, the second source region S2 may be electrically connected to the first gate electrode GE1 through a sixth conductive pattern CP6 (or the second source electrode of the second transistor T2). The second drain region D2 may be integrated with the third source region S3. The second drain region D2 and the third source region S3 may be electrically connected to a second capacitor electrode CPE2 (or the second drain electrode of the second transistor T2 and the third source electrode of the third transistor T3). The third drain region D3 may be electrically connected to the first drain region D1 and the first electrode AE of the light-emitting element ED through at least one conductive pattern, including a fifth conductive pattern CP5 (or the third drain electrode of the third transistor T3).

The fifth insulating layer GI5 may be disposed on the fourth insulating layer GI4 and the second semiconductor layer SCL2, and may cover the semiconductor patterns of the second semiconductor layer SCL2. For example, the fifth insulating layer GI5 may cover the second active layer ACT2 and the third active layer ACT3.

The fourth conductive layer GTLA may be disposed on the fifth insulating layer GI5. The fourth conductive layer GTLA may include conductive patterns that contain a conductive material. For example, the fourth conductive layer GTLA may include the second gate electrode GE2 and the third gate electrode GE3 included in the second transistor T2 and the third transistor T3, respectively, of the pixel PX. The second gate electrode GE2 may be electrically connected to the first scan line GWL in FIG. 2. For example, the second gate electrode GE2 and the first scan line GWL may be integrally formed, but the present disclosure is not limited thereto. The third gate electrode GE3 may be electrically connected to the second scan line GCL in FIG. 2. For example, the third gate electrode GE3 and the second scan line GCL may be integrally formed, but the present disclosure is not limited thereto.

In one embodiment, the fourth conductive layer GTL4 may further include at least one conductive pattern that forms another electrode of at least one circuit element included in the pixel PX or a connection pattern electrically connected to the at least one circuit element. In other words, the fourth conductive layer GTL4 may additionally include at least one conductive pattern that serves as another electrode for at least one circuit element within the pixel PX or as a connection pattern electrically linked to the circuit element. For example, the fourth conductive layer GTL4 may further include the first, second, third, and fourth conductive patterns CP1, CP2, CP3, and CP4 of the pixel PX.

The first conductive pattern CP1 may be electrically connected to a region of the first active layer ACT1 through multiple insulating layers disposed between the substrate SUB and the sixth conductive layer GTL6. For example, the first conductive pattern CP1 may be electrically connected to the first drain region D1 through a first contact hole CH1, which is formed in the first insulating layer GI1, the second insulating layer GI2, the third insulating layer GI3, the fourth insulating layer GI4, and the fifth insulating layer GI5 to expose a portion of the first drain region D1. For example, the first conductive pattern CP1 may be in direct contact with the first drain region D1 exposed by the first contact hole CH1. In one embodiment, the first conductive pattern CP1 may function as the drain electrode of the first transistor T1 and may be regarded as an integral part of the first transistor T1.

The second conductive pattern CP2 may be electrically connected to another region of the first active layer ACT1 through multiple insulating layers disposed between the substrate SUB and the sixth conductive layer GTL6. For example, the second conductive pattern CP2 may be electrically connected to the first source region S1 through a second contact hole CH2, which is formed in the first insulating layer GI1, the second insulating layer GI2, the third insulating layer GI3, the fourth insulating layer GI4, and the fifth insulating layer GI5 to expose a portion of the first source region S1. In one embodiment, the second conductive pattern CP2 may function as the source electrode of the first transistor T1 and may be regarded as an integral part of the first transistor T1.

The third conductive pattern CP3 may be electrically connected to the first gate electrode GE1 through multiple insulating layers disposed between the first conductive layer GTL1 and the sixth conductive layer GTL6. For example, the third conductive pattern CP3 may be electrically connected to the first gate electrode GE1 through a third contact hole CH3, which is formed in the second insulating layer GI2, the third insulating layer GI3, the fourth insulating layer GI4, and the fifth insulating layer GI5 to expose a portion of the first gate electrode GE1. In one embodiment, the third conductive pattern CP3 may serve as a connection pattern that establishes a first node N1.

The fourth conductive pattern CP4 may be electrically connected to the first capacitor electrode CPE1 through multiple insulating layers disposed between the second conductive layer GTL2 and the sixth conductive layer GTL6. For example, the fourth conductive pattern CP4 may be electrically connected to the first capacitor electrode CPE1 through a fourth contact hole CH4, which is formed in the third insulating layer GI3, the fourth insulating layer GI4, and the fifth insulating layer GI5 to expose a portion of the first capacitor electrode CPE1. In one embodiment, the fourth conductive pattern CP4 may be a connection pattern that connects the first capacitor electrode CPE1 and the initialization voltage line VIL.

The sixth insulating layer GI6 may be disposed on the fifth insulating layer GI5 and the fourth conductive layer GTL4, and may cover the conductive patterns of the fourth conductive layer GTL4. For example, the sixth insulating layer GI6 may cover the second and third gate electrodes GE2 and GE3 and the first, second, third, and fourth conductive patterns CP1, CP2, CP3, and CP4.

The fifth conductive layer SDL1 may be disposed on the sixth insulating layer GI6. The fifth conductive layer SDL1 may include conductive patterns that contain a conductive material. For example, the fifth conductive layer SDL1 may include the second capacitor electrode CPE2 of the pixel PX. The second capacitor electrode CPE2 may overlap with the data line DL connected to the pixel PX (or the second electrode of the second capacitor C2, which is electrically connected to the data line DL), and the second capacitor C2 may be formed by the second capacitor electrode CPE2 and the data line DL. The second capacitor electrode CPE2 and the data line DL may form the first and second electrodes, respectively, of the second capacitor C2.

The second capacitor electrode CPE2 may be electrically connected to regions of the second and third active layers ACT2 and ACT3 through multiple insulating layers disposed between the second semiconductor layer SCL2 and the fifth conductive layer SDL1. For example, the second capacitor electrode CPE2 may be electrically connected to the second drain region D2 and the third source region S3 through a twelfth contact hole CH12, which is formed in the fifth insulating layer GI5 and the sixth insulating layer GI6 to expose portions of the second drain region D2 and the third source region S3. In one embodiment, the second capacitor electrode CPE2 may function as the drain electrode of the second transistor T2 and the source electrode of the third transistor T3. The second capacitor electrode CPE2 may also be considered as an integral part of the second and third transistors T2 and T3. For example, the second capacitor C2, the second transistor T2, and the third transistor T3 may share a single electrode commonly connected to the third node N3.

In one embodiment, the fifth conductive layer SDL1 may further include at least one conductive pattern that serves as another electrode for at least one circuit element included in the pixel PX or as a connection pattern electrically connected to the at least one circuit element. For example, the fifth conductive layer SDL1 may further include the fifth and sixth conductive patterns CP5 and CP6 of the pixel PX.

The fifth conductive pattern CP5 may be electrically connected to the first conductive pattern CP1 through an insulating layer disposed between the fourth conductive layer GTL4 and the fifth conductive layer SDL1. For example, the fifth conductive pattern CP5 may be electrically connected to the first conductive pattern CP1 through a fifth contact hole CH5, which is formed in the sixth insulating layer GI6 to expose a portion of the first conductive pattern CP1. Additionally, the fifth conductive pattern CP5 may be electrically connected to another region of the third active layer ACT3 through multiple insulating layers disposed between the second semiconductor layer SCL2 and the fifth conductive layer SDL1. For example, the fifth conductive pattern CP5 may be electrically connected to the third drain region D3 through a sixth contact hole CH6, which is formed in the fifth insulating layer GI5 and the sixth insulating layer GI6 to expose a portion of the third drain region D3. In one embodiment, the fifth conductive pattern CP5 may serve as the drain electrode of the third transistor T3 and may be regarded as an integral part of the third transistor T3.

The sixth conductive pattern CP6 may be electrically connected to the third conductive pattern CP3 through an insulating layer disposed between the fourth conductive layer GTL4 and the fifth conductive layer SDL1. For example, the sixth conductive pattern CP6 may be electrically connected to the third conductive pattern CP3 through a seventh contact hole CH7, which is formed in the sixth insulating layer GI6 to expose a portion of the third conductive pattern CP3. Additionally, the sixth conductive pattern CP6 may be electrically connected to another region of the second active layer ACT2 through multiple insulating layers disposed between the second semiconductor layer SCL2 and the fifth conductive layer SDL1. For example, the sixth conductive pattern CP6 may be electrically connected to the second source region S2 through an eighth contact hole CH8, which is formed in the fifth insulating layer GI5 and the sixth insulating layer GI6 to expose a portion of the second source region S2. In one embodiment, the sixth conductive pattern CP6 may serve as the source electrode of the second transistor T2 and may be regarded as an integral part of the second transistor T2.

The seventh insulating layer ILD1 may be disposed on the sixth insulating layer GI6 and the fifth conductive layer SDL1, and may cover the conductive patterns of the fifth conductive layer SDL1. For example, the seventh insulating layer ILD1 may cover the second capacitor electrode CPE2 and the fifth and sixth conductive patterns CP5 and CP6.

The sixth conductive layer SDL2 may be disposed on the seventh insulating layer ILD1. The sixth conductive layer SDL2 may include conductive patterns that contain a conductive material. For example, the sixth conductive layer SDL2 may include the data line DL connected to the pixel PX (or the second electrode of the second capacitor C2). The data line DL may form the second capacitor C2 together with the second capacitor electrode CPE2.

The eighth insulating layer ILD2 may be disposed on the seventh insulating layer ILD1 and the sixth conductive layer SDL2, and may cover the conductive patterns of the sixth conductive layer SDL2. For example, the eighth insulating layer ILD2 may cover the data line DL.

The seventh conductive layer SDL3 may be disposed on the eighth insulating layer ILD2. The seventh conductive layer SDL3 may include conductive patterns that contain a conductive material. For example, the seventh conductive layer SDL3 may include the first voltage line VDL and the initialization voltage line VIL. In one embodiment, the seventh conductive layer SDL3 may further include the seventh conductive pattern CP7 of the pixel PX.

The first voltage line VDL may be electrically connected to the second conductive pattern CP2 through multiple insulating layers disposed between the fourth conductive layer GTL4 and the seventh conductive layer SDL3. For example, the first voltage line VDL may be electrically connected to the second conductive pattern CP2 through a ninth contact hole CH9, which is formed in the sixth insulating layer GI6, the seventh insulating layer ILD1, and the eighth insulating layer ILD2 to expose a portion of the second conductive pattern CP2. The first voltage line VDL may be electrically connected to the first source region S1 through the second conductive pattern CP2.

The initialization voltage line VIL may be electrically connected to the fourth conductive pattern CP4 through multiple insulating layers disposed between the fourth conductive layer GTL4 and the seventh conductive layer SDL3. For example, the initialization voltage line VIL may be electrically connected to the fourth conductive pattern CP4 through a tenth contact hole CH10, which is formed in the sixth insulating layer GI6, the seventh insulating layer ILD1, and the eighth insulating layer ILD2 to expose a portion of the fourth conductive pattern CP4. The initialization voltage line VIL may be electrically connected to the first capacitor electrode CPE1 through the fourth conductive pattern CP4.

The seventh conductive pattern CP7 may be electrically connected to the fifth conductive pattern CP5 through an insulating layer disposed between the fifth conductive layer SDL1 and the seventh conductive layer SDL3. For example, the seventh conductive pattern CP7 may be electrically connected to the fifth conductive pattern CP5 through an eleventh contact hole CH11, which is formed in the seventh insulating layer ILD1 and the eighth insulating layer ILD2 to expose a portion of the fifth conductive pattern CP5. The seventh conductive pattern CP7 may be electrically connected to the third drain region D3 and the first conductive pattern CP1 through the fifth conductive pattern CP5. Additionally, the seventh conductive pattern CP7 may be electrically connected to the first drain region D1 through the first conductive pattern CP1. In one embodiment, the seventh conductive pattern CP7 may serve as a connection pattern that forms the second node N2.

In one embodiment, the seventh conductive layer SDL3 may further include the second voltage line VSL of FIG. 2, but the present disclosure is not limited thereto. Alternatively, the second voltage line VSL may be disposed in another conductive layer included in the circuit layer CRL. The second voltage line VSL may be electrically connected to the second electrode CE of the light-emitting element ED either within or around the display area DA.

The ninth insulating layer VIA may be disposed on the eighth insulating layer ILD2 and the seventh conductive layer SDL3, and may cover the conductive patterns of the seventh conductive layer SDL3. For example, the ninth insulating layer VIA may cover the first voltage line VDL, the initialization voltage line VIL, and the seventh conductive pattern CP7.

The patterns included in each conductive layer of the circuit layer CRL, such as the electrodes, the connection patterns (e.g., the first through seventh conductive patterns CP1 through CP7), and/or the wiring patterns, may comprise single-layer or multi-layer structures that contain at least one conductive material. For example, the conductive patterns included in each of the first conductive layer GTL1, the second conductive layer GTL2, the third conductive layer GTL3, the fourth conductive layer GTL4, the fifth conductive layer SDL1, the sixth conductive layer SDL2, and the seventh conductive layer SDL3 may contain at least one of molybdenum (Mo), aluminum (Al), chromium (Cr), gold (Au), silver (Ag), titanium (Ti), nickel (Ni), neodymium (Nd), copper (Cu), or other metals, their alloys, or other conductive materials, and may have a single-layer or multi-layer structure. At least two of the conductive layers of the circuit layer CRL may include the same material or different materials. In one embodiment, the patterns included in the same conductive layer may be formed simultaneously using the same conductive material.

The insulating layers of the circuit layer CRL may include at least one insulating material and may have a single-layer or multi-layer structure. For example, the first insulating layer GI1, the second insulating layer GI2, the third insulating layer GI3, the fourth insulating layer GI4, the fifth insulating layer GI5, the sixth insulating layer GI6, the seventh insulating layer ILD1, the eighth insulating layer ILD2, and the ninth insulating layer VIA may include an organic insulating material and/or an inorganic insulating material and may have a single-layer or multi-layer structure. At least two of the insulating layers of the circuit layer CRL may include the same material or different materials.

In one embodiment, the first insulating layer GI1, the second insulating layer GI2, the third insulating layer GI3, the fourth insulating layer GI4, the fifth insulating layer GI5, the sixth insulating layer GI6, the seventh insulating layer ILD1, and the eighth insulating layer ILD2 may be single-layer or multi-layer inorganic insulating layers that include an inorganic insulating material (e.g., silicon nitride, silicon oxide, silicon oxynitride, titanium oxide, aluminum oxide, or other inorganic insulating materials). Therefore, the circuit elements disposed in the circuit layer CRL can be adequately protected, ensuring reliability while reducing or minimizing the thickness of the circuit layer CRL.

In one embodiment, the ninth insulating layer VIA may include an organic insulating material (e.g., an acrylic resin, an epoxy resin, a phenolic resin, a polyamide resin, a polyimide resin, or other organic insulating materials). The upper surface of the ninth insulating layer VIA may be substantially flat. Thus, the upper surface of the ninth insulating layer VIA may be substantially flat. However, the present disclosure is not limited to this. For example, the ninth insulating layer VIA may be formed using an inorganic insulating material and then flattened through a planarization process. The material and/or structure of each insulating layer of the circuit layer CRL may vary according to embodiments.

FIG. 3 illustrates that the contact holes of the circuit layer CRL have substantially the same or similar widths and shapes and are entirely filled by their respective conductive patterns. However, the sizes or shapes of these contact holes and conductive patterns may vary depending on the embodiment. Additionally, conductive patterns connected to patterns underlying patterns may either completely or partially fill the contact holes.

In one embodiment, the number and/or size of the contact holes formed in the circuit layer CRL may be reduced or minimized. For example, in a high-resolution display device with smaller pixels PX, the number and/or size of the contact holes may be reduced to optimize the design of the circuit layer CRL. For example, at least some of the first through twelfth contact holes CH1 through CH12 located within each pixel region may have narrower widths and smaller areas, achieving a relatively large aspect ratio (e.g., the ratio of the maximum depth in the third direction DR3 to the maximum width in the first direction DR1 or second direction DR2). However, as the aspect ratio of the contact holes increases, it may become challenging to properly fill the contact holes with a conductive material, potentially resulting in reduced contact quality or disconnections.

For example, in the case of contact holes that penetrate numerous insulating layers, such as the first contact hole CH1 or the second contact hole CH2, reducing the width or area of these contact holes may significantly increase their aspect ratio. For example, if the width or area of deep contact holes such as the first contact hole CH1 or the second contact hole CH2 is reduced, resulting in an aspect ratio of 0.6 or greater, or even 1 or greater, it may become difficult to properly fill these contact holes with a conductive material, thereby increasing the likelihood of contact defects.

The light-emitting element layer EDL may be disposed on the circuit layer CRL and may be located in the display area DA. For example, the light-emitting element layer EDL may be disposed on the circuit layer CRL in the display area DA.

The light-emitting element layer EDL may include a pixel defining layer PDL that defines an emission area EA of the pixel PX and a light-emitting element ED that is disposed in the emission area EA of the pixel PX. In one embodiment, the light-emitting element layer EDL may further include a spacer disposed on a portion of the pixel defining layer PDL.

The light-emitting element ED may include a first electrode AE (e.g., an anode), a second electrode CE (e.g., a cathode), and an emission layer EL disposed between the first electrode AE and the second electrode CE. In one embodiment, the first electrode AE, the emission layer EL, and the second electrode CE may be sequentially stacked on the circuit layer CRL along the third direction DR3.

In one embodiment, the light-emitting element ED may further include at least one intermediate layer. For example, the light-emitting element ED may further include a first intermediate layer (e.g., a hole transport layer including a hole injection layer) disposed between the first electrode AE and the emission layer EL, and a second intermediate layer (e.g., an electron transport layer including an electron injection layer) disposed between the emission layer EL and the second electrode CE. In one embodiment, at least one intermediate layer may be a common film formed across the entire display area DA.

FIG. 3 illustrates an embodiment where the light-emitting element ED includes a single emission layer EL, but the present disclosure is not limited thereto. For example, the light-emitting element ED may be formed with a tandem structure comprising at least two emission layers (e.g., the emission layer EL of FIG. 3 and an additional emission layer overlapping with the emission layer EL) stacked in the third direction DR3. Additionally, the light-emitting element ED may further include a charge generation layer disposed between the at least two emission layers. The emission layer EL may be formed as a common film across the entire display area DA, or may be disposed in each pixel region in a shape and/or size corresponding to the emission area EA of each pixel PX.

In one embodiment, the display device 10 may additionally include an optical layer positioned on the light-emitting element layer EDL. The optical layer may comprise a color filter layer (e.g., a color filter layer containing filters corresponding to the emission colors of the pixels PX) and/or a light conversion layer (e.g., a layer with wavelength conversion patterns that adjust the color or wavelength of light emitted by the light-emitting elements ED in at least some pixels PX). This configuration allows the color or wavelength of the light emitted from the pixels PX to be appropriately controlled. The optical layer may be selectively included in the display device 10 based on design requirements. For instance, depending on the type or structure of the light-emitting elements ED or the light-emitting element layer EDL, the display device 10 may include one or more optical layers as necessary.

The first electrode AE of the light-emitting element ED may be disposed on the circuit layer CRL. For example, the first electrode AE may be disposed on the ninth insulating layer VIA corresponding to the emission area EA.

The light-emitting element ED may be electrically connected to the first transistor T1. For example, the first electrode AE of the light-emitting element ED may be electrically connected to the seventh conductive pattern CP7 through a via hole VH, which is formed in the ninth insulating layer VIA, and may be electrically connected to the first drain region D1 of the first transistor T1 through the seventh conductive pattern CP7, the fifth conductive pattern CP5, and the first conductive pattern CP1. The first electrode AE may include at least one conductive material and may have a single-layer or multi-layer structure. In one embodiment, the first electrode AE may include a reflective electrode layer containing a high-reflectivity metal material.

FIG. 3 illustrates an embodiment where the first electrode AE of the light-emitting element ED is directly disposed on the circuit layer CRL, but the present disclosure is not limited thereto. For example, the emission layer EL may be formed across the entire display area DA, and an additional electrode or pattern may be disposed below the first electrode AE of the light-emitting element ED to adjust or optimize the resonance distance of the light generated by the light-emitting element ED in accordance with the emission wavelength of the pixel PX. The additional electrode or pattern may be disposed between the circuit layer CRL and the light-emitting element layer EDL or within the circuit layer CRL or light-emitting element layer EDL (e.g., in the upper portion of the circuit layer CRL or the lower portion of the light-emitting element layer EDL).

The emission layer EL of the light-emitting element ED may include a polymer material or a low-molecular-weight material. The light emitted from the emission layer EL may contribute to the display of an image. In one embodiment, the emission layer EL may be provided for the pixel PX, and the emission layer EL of the pixel PX may emit visible light of a color or wavelength corresponding to the pixel PX. In another embodiment, the emission layer EL may be a common layer shared by multiple pixels PX of different colors, and at least some of the emission areas EA of the multiple pixels PX may be provided with a light conversion layer and/or color filters corresponding to the color (or wavelength) of light to be emitted from the respective multiple pixels PX.

The second electrode CE of the light-emitting element ED may include a conductive material. In one embodiment, the second electrode CE may be a common layer formed across the entire display area DA in a shape that covers the emission layer EL and the pixel defining layer PDL. In one embodiment, the second electrode CE may include a transparent conductive oxide (TCO) such as indium tin oxide (ITO) or indium zinc oxide (IZO), or a semi-transmissive conductive material such as magnesium (Mg), silver (Ag), or an alloy of Mg and Ag.

The pixel defining layer PDL may be formed to cover the edges of the first electrode AE of the light-emitting element ED while including an opening that exposes the remaining portion of the first electrode AE. The overlapping area between the exposed portion of the first electrode AE and the emission layer EL (or a region including this overlapping area) may be defined as the emission area EA of the pixel PX.

In one embodiment, the pixel defining layer PDL may include an organic insulating material. For example, the pixel defining layer PDL may include a polyacrylate resin, an epoxy resin, a phenolic resin, a polyamide resin, a polyimide resin, an unsaturated polyester resin, a polyphenylenether resin, a polyphenylene sulfide resin, or benzocyclobutene (BCB), or other organic insulating materials.

The encapsulation layer TFEL may be disposed on the light-emitting element layer EDL. The encapsulation layer TFEL may cover the light-emitting element layer EDL in the display area DA and may extend into the non-display area NDA to contact the circuit layer CRL. For example, the encapsulation layer TFEL may be disposed in the display area DA to cover the light-emitting element layer EDL, with its edge extending into a portion of the non-display area NDA adjacent to the display area DA. The encapsulation layer TFEL may prevent the infiltration of oxygen or moisture into the light-emitting element layer EDL and reduce electrical and/or physical impacts on the circuit layer CRL and the light-emitting element layer EDL.

In one embodiment, the encapsulation layer TFEL may be a multi-layer structure including inorganic and organic encapsulation layers. For example, the encapsulation layer TFEL may include a first inorganic encapsulation layer TFE1, an organic encapsulation layer TFE2, and a second inorganic encapsulation layer TFE3 that are sequentially disposed on the light-emitting element layer EDL. The encapsulation layer TFEL may also be replaced with other types, structures, and/or materials of encapsulation members. For example, the light-emitting element layer EDL may be encapsulated using an upper substrate including an insulating material such as glass, or a protective layer including a single or multi-layer capping layer.

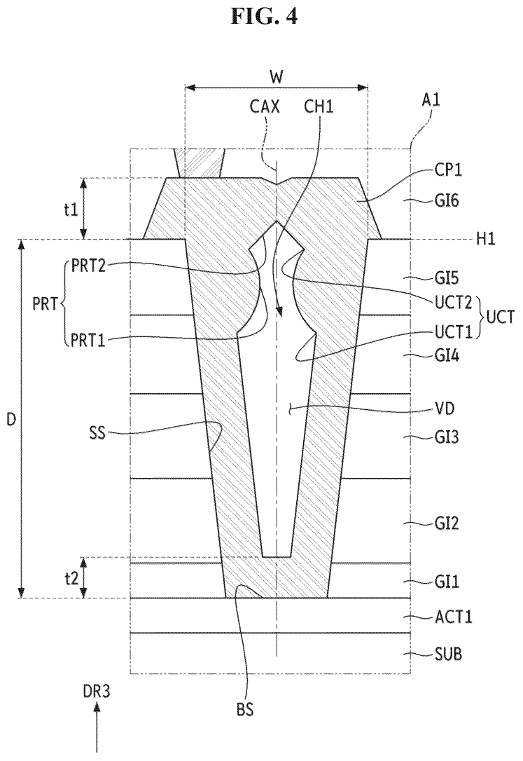

FIG. 4 is a cross-sectional view illustrating a conductive pattern according to an embodiment. For example, FIG. 4 provides a detailed illustration of the first conductive pattern CP1 disposed in part A1 of FIG. 3.

Referring to FIGS. 3 and 4, the first conductive pattern CP1 may be disposed within and around the first contact hole CH1. For example, a first portion of the first conductive pattern CP1 located at a height less than or equal to a first height H1, which corresponds to the maximum height of the first contact hole CH1, may be disposed within the first contact hole CH1, and a second portion of the first conductive pattern CP1 located at a greater height than the first height H1 may be disposed above the first contact hole CH1 and may extend around the first contact hole CH1. In other words, the first portion of the first conductive pattern CP1 located at or below the first height H1, corresponding to the maximum height of the first contact hole CH1, may be disposed within the first contact hole CH1. The second portion of the first conductive pattern CP1, located above the first height H1, may be positioned above the first contact hole CH1 and extend around it. For example, the first conductive pattern CP1 may cover the first contact hole CH1 and may be disposed around the perimeter of the first contact hole CH1, on a plane (e.g., a plane intersecting the third direction DR3). In other words, the first conductive pattern CP1 may cover the first contact hole CH1 and extend around its perimeter on a plane, such as a plane intersecting the third direction DR3.

In one embodiment, the first contact hole CH1 may penetrate at least two insulating layers of the circuit layer CRL and may have a depth D that is greater than or equal to the thickness of the at least two insulating layers. In one embodiment, to appropriately position the first conductive pattern CP1 within the pixel region where the pixel PX is disposed and to ensure its electrical stability, the size of the first contact hole CH1 may be constrained. For example, a width W or the area of the first contact hole CH1 may be restricted to maintain the electrical stability of the circuit elements in the circuit layer CRL. As the width W or the area of the first contact hole CH1 decreases or is minimized, the aspect ratio (e.g., the depth D-to-width W ratio in FIG. 4) of the first contact hole CH1 may increase. For example, the aspect ratio of the first contact hole CH1 may be 0.3 or greater.

In one embodiment, the display device 10 may be a high-resolution display device with a highly integrated circuit layer CRL, where the area occupied by the first contact hole CH1 is further reduced or minimized. Consequently, the aspect ratio of the first contact hole CH1 may increase. To accommodate the circuit elements of the pixel circuit within a confined pixel region, the circuit layer CRL may include additional semiconductor layers and/or conductive layers. Furthermore, the number of insulating layers in the circuit layer CRL may also increase. As a result, the depth D of at least one contact hole, including the first contact hole CH1, may increase.

When the first contact hole CH1 has a limited width or area and penetrates multiple insulating layers, the aspect ratio of the first contact hole CH1 may increase as its depth D increases. For example, the first contact hole CH1 may be formed to sequentially penetrate the first insulating layer GI1, the second insulating layer GI2, the third insulating layer GI3, the fourth insulating layer GI4, and the fifth insulating layer GI5, and the aspect ratio of the first contact hole CH1 may be 0.6 or greater, or 1 or greater. For example, to optimize the design of the circuit layer CRL, the first contact hole CH1 may be formed with a depth D greater than its width W, and the aspect ratio of the first contact hole CH1 may be 1 or greater.

As the depth D of the first contact hole CH1 increases, the likelihood of the first conductive pattern CP1 not being adequately filled within the first contact hole CH1 during its formation may increase. For example, with an increase in depth D, the conductive film formation process for forming the first conductive pattern CP1 may result in excessive deposition of the conductive film at or near the entrance of the first contact hole CH1. This excessive deposition can cause an overhang, potentially blocking or covering the entrance of the narrow first contact hole CH1. Consequently, the conductive film may not be adequately formed within the first contact hole CH1 (e.g., on a side surface SS and/or a bottom surface BS of the first contact hole CH1).

To address this issue, in one embodiment, the first conductive pattern CP1 may be formed using at least two conductive film formation processes. In this approach, the initially deposited conductive film may be partially etched to prevent it from obstructing the entrance of the first contact hole CH1. Subsequently, an additional conductive film deposition may be performed. This method allows a conductive film of the desired thickness to be properly deposited within the first contact hole CH1, particularly on the side surface SS and bottom surface BS, thereby improving or ensuring the quality of the electrical contact.

In one embodiment, when the first conductive pattern CP1 is formed by at least two conductive film formation processes, a thickness t2 of the first conductive pattern CP1 on the bottom surface BS of the first contact hole CH1 may be 15% or more of a thickness t1 of an upper portion of the first conductive pattern CP1 around the first contact hole CH1. In one embodiment, when the aspect ratio of the first contact hole CH1 is large (e.g., 0.6 or greater or 1 or greater), multiple conductive film formation processes may be performed to ensure the stability of the electrical connection provided by the first conductive pattern CP1. Accordingly, the thickness t2 of the first conductive pattern CP1 on the bottom surface BS of the first contact hole CH1 may further increase. For example, the thickness t2 of the first conductive pattern CP1 on the bottom surface BS of the first contact hole CH1 may be 50% or more of the thickness t1 of the upper portion of the first conductive pattern CP1 around the first contact hole CH1. If the thickness t2 of the first conductive pattern CP1 on the bottom surface BS of the first contact hole CH1 is 50% or more of the thickness t1 of the upper portion of the first conductive pattern CP1, the first conductive pattern CP1 can be stably connected to the underlying pattern (e.g., the first active layer ACT1) even when the aspect ratio of the first contact hole CH1 increases.

Additionally, in one embodiment, the initially deposited conductive film may be etched without requiring an additional mask process (e.g., a photolithography process using a mask), thereby simplifying the manufacturing process of the display device 10 and enhancing manufacturing efficiency. A detailed explanation of a method for forming the first conductive pattern CP1 according to one embodiment will be provided later.

The first conductive pattern CP1 formed according to the above-described embodiments may cover the side surface SS and the bottom surface BS of the first contact hole CH1 and extend to the upper portion of the first contact hole CH1. Additionally, from a cross-sectional perspective, the first conductive pattern CP1 may include at least two protrusions PRT extending in the direction of a central axis CAX of the first contact hole CH1. In other words, the at least two protrusions PRT may extend toward the central axis CAX of the first contact hole CH1. For example, from a cross-sectional perspective, the first conductive pattern CP1 may include a first protrusion PRT1 and a second protrusion PRT2 located at different heights and extending toward the central axis CAX of the first contact hole CH1. The first and second protrusions PRT1 and PRT2 may have relatively greater thicknesses compared to other surrounding areas. Additionally, the first conductive pattern CP1 may include undercut-shaped recesses UCT disposed around the first and second protrusions PRT1 and PRT2. For example, the lower end of the first protrusion PRT1 may meet a first recess UCT1, and the upper end of the first protrusion PRT1 may meet a second recess UCT2. If the first conductive pattern CP1 includes the first and second protrusions PRT1 and PRT2 at different heights, the second recess UCT2 may be disposed between the first and second protrusions PRT1 and PRT2. When the second protrusion PRT2 is disposed at the uppermost portion of the first conductive pattern CP1, the second protrusion PRT2 may either connect with or be considered part of the upper portion of the first conductive pattern CP1.

In one embodiment, the first and second protrusions PRT1 and PRT2, which are sequentially formed through at least two conductive film formation processes, may be disposed at different heights and have different thicknesses. For example, the first protrusion PRT1 may protrude from the side surface SS of the first contact hole CH1 toward the central axis CAX of the first contact hole CH1 at a height that is less than or equal to the first height H1 of the first contact hole CH1. The second protrusion PRT2 may be positioned at a height that is greater than that of the first protrusion PRT1, and may protrude from the side surface SS and/or upper portion of the first contact hole CH1 toward the central axis CAX of the first contact hole CH1.

In one embodiment, the second protrusion PRT2 may have a greater thickness than the first protrusion PRT1 relative to the side surface SS of the first contact hole CH1 and may extend further toward the central axis CAX of the first contact hole CH1. For example, the first protrusion PRT1 may have a thickness that is smaller than half the width W of the first contact hole CH1 and may be spaced apart from the central axis CAX of the first contact hole CH1. In one example, the first conductive pattern CP1 may only partially fill the first contact hole CH1, resulting in a void VD surrounded by the first conductive pattern CP1 within the first contact hole CH1. The second protrusion PRT2 may have a greater thickness than the first protrusion PRT1, and may be closer to or meet the central axis CAX of the first contact hole CH1. For example, the upper portion of the first conductive pattern CP1, including the second protrusion PRT2, may fully cover the entrance of the first contact hole CH1. In one embodiment, the thickness of the second protrusion PRT2 may gradually increase from the bottom to the top, and the void VD surrounded by the first conductive pattern CP1 may be present beneath the second protrusion PRT2. In one embodiment, a single void VD may exist inside the first contact hole CH1; however, the present disclosure is not limited thereto. For example, the first contact hole CH1 may include one or more voids VD depending on factors such as the thickness of the conductive film of the number of deposition processes. The number or size of voids VD may vary according to embodiments.

In one embodiment, if the first conductive pattern CP1 has an increased thickness in the region of the first contact hole CH1 to form at least two protrusions PRT, the upper surface of the first conductive pattern CP1 extending beyond the protrusions PRT may be relatively flat. For example, the second protrusion PRT2 may completely cover the entrance of the first contact hole CH1, and the upper surface of the first conductive pattern CP1 may be substantially flat. The term “substantially flat” may refer to an upper surface of the first conductive pattern CP1 with undulations below a predetermined threshold. For example, the upper surface of the first conductive pattern CP1 may be completely flat without any undulations, or may include shallow grooves or minor protrusions with heights below the predetermined threshold, resulting in a relatively flat surface. For example, as illustrated in FIG. 4, the upper surface of the first conductive pattern CP1 may have a shallow groove at the point where it intersects the central axis CAX of the first contact hole CH1, but otherwise remain generally flat. Alternatively, the upper surface of the first conductive pattern CP1 may be completely flat.

If the upper surface of the first conductive pattern CP1 in the region of the first contact hole CH1 is not flat, forming another contact hole (e.g., the fifth contact hole CH5 in FIG. 3) directly over the first conductive pattern CP1 within the first contact hole CH1 may be challenging. Consequently, the width of the first conductive pattern CP1 might need to be increased, and another contact hole would have to be formed over the first conductive pattern CP1 in a region that does not overlap with the first contact hole CH1. On the other hand, if the upper surface of the first conductive pattern CP1 in the region of the first contact hole CH1 is substantially flat, as in this embodiment, another contact hole (e.g., the fifth contact hole CH5 in FIG. 3) can be easily and appropriately formed directly over the first conductive pattern CP1 within the first contact hole CH1. For example, in this embodiment, the first and fifth contact holes CH1 and CH5 may be arranged to overlap in the third direction DR3. This configuration allows the width or area of the first conductive pattern CP1 to be reduced or minimized, while also improving or ensuring the electrical stability between the first conductive pattern CP1 and adjacent conductive patterns.

According to this embodiment, by reliably forming the first conductive pattern CP1 within the first contact hole CH1, the contact quality provided by the first conductive pattern CP1 can be improved. As a result, even if the display device 10 includes deep contact holes with large aspect ratios, such as the first contact hole CH1, the display device 10 can effectively prevent contact defects and ensure stable transmission of electrical signals.

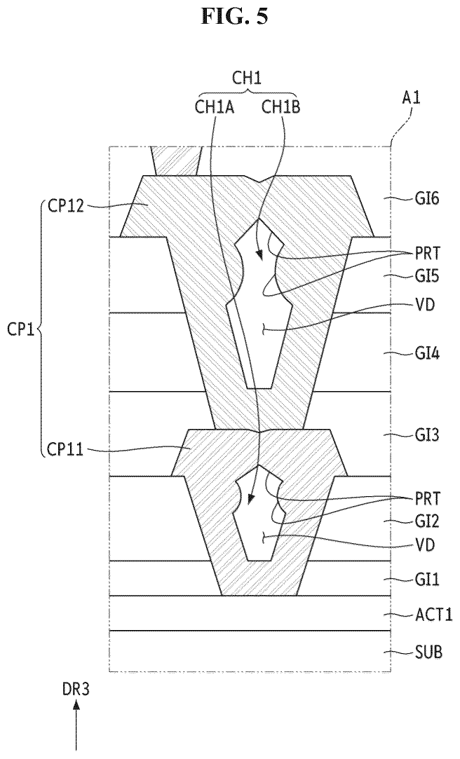

FIG. 5 is a cross-sectional view illustrating a conductive pattern according to an embodiment. For example, FIG. 5 provides another detailed illustration of the first conductive pattern CP1 disposed in part A1 of FIG. 3. The embodiment of FIG. 5 differs from the embodiment of FIG. 4 in that the first conductive pattern CP1 has a multi-layer structure including multiple conductive patterns. In describing the following embodiments, components that are substantially identical or similar to those described in at least one of the previous embodiments are assigned the same reference numerals, and redundant explanations thereof will be omitted.

Referring to FIG. 5, the first contact hole CH1 may include at least two sub-contact holes sequentially arranged along the third direction DR3. For example, the first contact hole CH1 may include a lower contact hole CH1A, which penetrates some of the insulating layers through which the first contact hole CH1 passes, and an upper contact hole CH1B, which is disposed on the lower contact hole CH1A and penetrates other insulating layers through which the first contact hole CH1 passes. The lower contact hole CH1A and the upper contact hole CH1B may overlap from a planar perspective. For example, the lower contact hole CH1A and the upper contact hole CH1B may overlap in the third direction DR3.

The lower contact hole CH1A and the upper contact hole CH1B may each be formed to penetrate at least one insulating layer. In one embodiment, the lower contact hole CH1A and the upper contact hole CH1B may each penetrate at least two insulating layers. For example, the lower contact hole CH1A may be formed in the first and second insulating layers GI1 and GI2 to expose a portion of the first active layer ACT1, and the upper contact hole CH1B may be formed in the third, fourth, and fifth insulating layers GI3 GI4, and GI5 to expose a portion of a lower conductive pattern CP11 that fills the lower contact hole CH1A.

The first conductive pattern CP1 may include the lower conductive pattern CP11 covering the lower contact hole CH1A and an upper conductive pattern CP12 covering the upper contact hole CH1B. The lower conductive pattern CP11 may cover the side surface and bottom surface of the lower contact hole CH1A and extend to the upper portion of the lower contact hole CH1A. The lower conductive pattern CP11 may overlap the upper surface of the second insulating layer GI2. The upper conductive pattern CP12 may cover the side surface and bottom surface of the upper contact hole CH1B and extend to the upper portion of the upper contact hole CH1B. The upper conductive pattern CP12 may overlap the upper surface of the fifth gate insulating layer GI5. In one embodiment, the lower contact hole CH1A and the upper contact hole CH1B may be disposed in the second conductive layer GTL2 and the fourth conductive layer GTL4, respectively, but the present disclosure is not limited thereto. For example, the positions of the lower contact hole CH1A and the upper contact hole CH1B or the insulating layers through which each of the lower contact hole CH1A and the upper contact hole CH1B passes may vary.

At least one of the lower conductive pattern CP11 and the upper conductive pattern CP12 may be formed by at least two conductive film formation processes and at least one conductive film etching process. Accordingly, at least one of the lower contact hole CH1A and the upper contact hole CH1B may include at least two protrusions PRT that protrude toward the central axis CAX of the first contact hole CH1 from a cross-sectional perspective. For example, the lower conductive pattern CP11 and the upper conductive pattern CP12 may each be formed using at least two conductive film deposition processes and at least one conductive film etching process. As a result, the lower conductive pattern CP11 may include at least two protrusions PRT protruding toward the central axis of the lower contact hole CH1A, and the upper conductive pattern CP12 may include at least two protrusions PRT protruding toward the central axis of the upper contact hole CH1B.

In one embodiment, the upper surface of the lower conductive pattern CP11 on the lower contact hole CH1A may be substantially flat. Additionally, the upper contact hole CH1B and the upper conductive pattern CP12 may be formed on the lower conductive pattern CP11 to overlap with the lower contact hole CH1A. Accordingly, the width or area of the first contact hole CH1 can be reduced or minimized.

As described above, by dividing the first contact hole CH1 into at least two overlapping contact holes and forming overlapping conductive patterns to fill these contact holes, the depth of each individual contact hole can be reduced. This facilitates the formation of the conductive patterns that fill the first contact hole CH1. Additionally, by ensuring that the upper surface of the lower conductive pattern CP11 is substantially flat, as in this embodiment, the at least two contact holes can be arranged to overlap in the third direction DR3. Consequently, the width or area of the first contact hole CH1 can be reduced or minimized, improving the design efficiency of the circuit layer CRL.

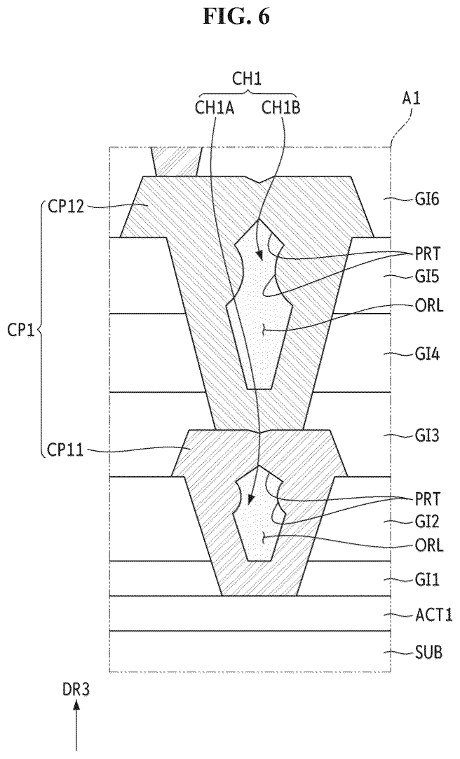

FIG. 6 is a cross-sectional view illustrating a conductive pattern according to an embodiment. For example, FIG. 6 provides another detailed illustration of the first conductive pattern CP1 disposed in part A1 of FIG. 3. The embodiment of FIG. 6 differs from the embodiment of FIG. 5 in that an organic layer ORL is disposed inside the first conductive pattern CP1.

Referring to FIG. 6, the display device 10 may further include the organic layer ORL filled in the space inside the first contact hole CH1 that is not filled by the first conductive pattern CP1. For example, the organic layer ORL may fill the voids VD shown in FIG. 5. FIG. 6 illustrates an embodiment where the organic layer ORL completely fills the space (e.g., the voids VD) surrounded by the first conductive pattern CP1, but the present disclosure is not limited thereto. For example, the organic layer ORL may fill only a portion of the space surrounded by the first conductive pattern CP1, leaving smaller voids (e.g., voids smaller than the voids VD of FIG. 5) within the first contact hole CH1.

In one embodiment, the organic layer ORL may be formed from an organic film used as a mask in at least one conductive film etching process performed during the formation of the first conductive pattern CP1. For example, at least one organic film used as a mask in the conductive film etching process during the formation of the first conductive pattern CP1 may be left to fill the space inside the first contact hole CH1.

However, the present disclosure is not limited to this. For example, in addition to the organic film used as a mask in the conductive film etching process, an organic material may be filled in the space inside the first contact hole CH1 through an additional process to form the organic layer ORL.

In one embodiment, the organic layer ORL may include a heat-resistant organic material capable of withstanding the processing temperatures of subsequent processes conducted after the formation of the first conductive pattern CP1. For example, if the maximum temperature of the subsequent processes conducted after the formation of the first conductive pattern CP1 is 260° C. or lower, the organic layer ORL may include an organic material with a heat resistance of 260° C. or higher. For example, the organic layer ORL may include a polyhedral oligomeric silsesquioxane (POSS)-based organic material, a photosensitive polyimide (PSPI)-based organic material, a silane-based organic material, acrylic, or other heat-resistant organic materials. Therefore, the reliability of the display device 10, which includes the organic layer ORL, can be secured.

By more thoroughly filling the interior of the first contact hole CH1 with the organic layer ORL, the voids within the first contact hole CH1 can be reduced or eliminated. As a result, the reliability of the display device 10, particularly the reliability of the electrical connection through the first contact hole CH1, can be improved.

FIG. 6 illustrates the structure where the space (e.g., the voids VD of FIG. 5) enclosed by the first conductive pattern CP1 is filled with the organic layer ORL. However, the present disclosure is not limited to this configuration. For example, the void VD shown in FIG. 4 may also be filled with the organic layer ORL.

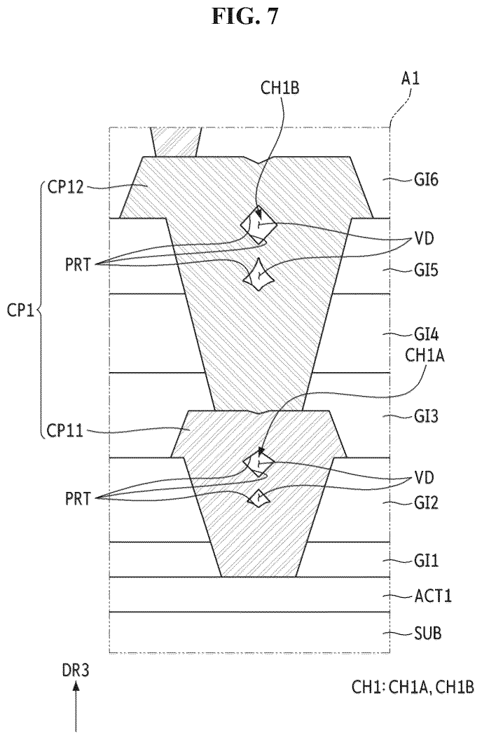

FIG. 7 is a cross-sectional view illustrating a conductive pattern according to an embodiment. For example, FIG. 7 provides another detailed illustration of the first conductive pattern CP1 disposed in part A1 of FIG. 3. FIG. 7 illustrates a different embodiment from the embodiment of FIG. 5 in terms of the thickness or shape of the first conductive pattern CP1.

Referring to FIG. 7, the first conductive pattern CP1 may have an increased thickness inside the first contact hole CH1, allowing it to fill the first contact hole CH1 more completely. For example, by increasing the number of conductive film formation processes when forming the first conductive pattern CP1, the thickness of the first conductive pattern CP1 filling the interior of the first contact hole CH1 can be increased. In one example, by increasing the number of conductive film deposition processes and etching processes used to form the first conductive pattern CP1 (or at least one of the lower and upper conductive patterns CP11 and CP12 that form the first conductive pattern CP1), the volume of the first conductive pattern CP1 filling the first contact hole CH1 may be increased. As a result, the size of voids VD inside the first contact hole CH1 can be reduced or minimized.

In one embodiment, each of the lower and upper conductive patterns CP11 and CP12 may be formed through at least four conductive film deposition processes and at least three conductive film etching processes. Accordingly, each of the lower and upper conductive patterns CP11 and CP12 may have a thicker cross-section and may include at least three protrusions PRT. For example, each of the lower conductive pattern CP11 and the upper conductive pattern CP12 may include at least three protrusions PRT protruding toward the central axes of the lower contact hole CH1A and the upper contact hole CH1B, respectively, from a cross-sectional perspective. All the protrusions PRT, except for the uppermost protrusion PRT, may be positioned below the height of each contact hole (e.g., the lower and upper contact holes CH1A and CH1B).

In one embodiment, as the number of conductive film formation processes used to form the first conductive pattern CP1 increases, the number and/or thickness of the protrusions PRT formed on the first conductive pattern CP1 may also increase. For example, if at least one protrusion PRT positioned at or below the height of the first contact hole CH1 (e.g., the first height H1 in FIG. 4) is formed with a thickness matching the cross-sectional area of the first contact hole CH1 at that height, the at least one protrusion PRT may reach the central axis CAX of the first contact hole CH1 at that height. Accordingly, the voids VD inside the first contact hole CH1 may be divided into smaller voids VD.

FIG. 7 illustrates an embodiment where the thickness and shape of the two-layer first conductive pattern CP1 of FIG. 5 have been changed, but the present disclosure is not limited thereto. For example, by changing the number of conductive film formation processes or the thickness of each deposited conductive film during the formation of the first conductive pattern CP1 of FIG. 4, the thickness and shape of the first conductive pattern CP1 of FIG. 4 may also be modified. In one example, the first conductive pattern CP1 of FIG. 4 may have a greater thickness and may include at least three protrusions PRT protruding toward the central axis CAX of the first contact hole CH1, from a cross-sectional perspective.

Furthermore, FIGS. 4 through 7 illustrate the first conductive pattern CP1 that fills the first contact hole CH1 as a conductive pattern formed in accordance with an embodiment, but the present disclosure is not limited thereto. For example, at least one of the aforementioned embodiments, including the embodiment of FIG. 4, may be applied to at least one conductive pattern (e.g., an electrode of a circuit element, a connection pattern, or wiring) that is partially disposed within a contact hole of the display device 10. Accordingly, the at least one conductive pattern may have a shape consistent with any one of the aforementioned embodiments (e.g., a shape featuring at least two protrusions when viewed from a cross-sectional perspective).

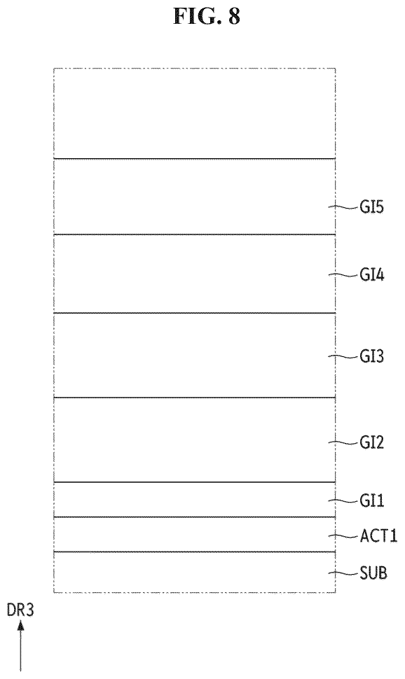

FIGS. 8 through 20 are cross-sectional views illustrating a method for manufacturing a display device according to an embodiment. For example, FIGS. 8 through 20 sequentially illustrate the steps for forming the first conductive pattern CP1 according to the embodiment of FIG. 4 during the manufacture of the display device 10 described in the embodiments of FIGS. 1 through 3. FIGS. 8 through 20 illustrate a portion of the display device 10 being manufactured, corresponding to part A1 of FIGS. 3 and 4.

Referring to FIGS. 3 and 8, on the substrate SUB (or on a buffer layer thereon), patterns of at least one semiconductor layer and/or conductive layer, which are disposed below the first conductive pattern CP1 and electrically connected to the first conductive pattern CP1 through the first contact hole CH1 (e.g., a semiconductor pattern such as the active layer of a transistor, and/or a conductive pattern such as an electrode, connection pattern, or wiring of a transistor or capacitor), may be formed. Insulating layers covering the patterns of the at least one semiconductor layer and/or conductive layer may also be formed. For example, the first semiconductor layer SCL1, including the first active layer ACT1, may be formed on the substrate SUB, and the first insulating layer GI1, the second insulating layer GI2, the third insulating layer GI3, the fourth insulating layer GI4, and the fifth insulating layer GI5 may be sequentially formed on the first semiconductor layer SCL1.

The first semiconductor layer SCL1 may be formed through a semiconductor film formation process (e.g., a deposition process) using at least one semiconductor material (e.g., a semiconductor material previously described as the material of the first active layer ACT1) and a semiconductor film patterning process (e.g., an etching process using a mask). Each of the first, second, third, fourth, and fifth insulating layers GI1, GI2, GI3, GI4, and GI5 may be formed through the formation of at least one insulating film (e.g., a deposition process) using at least one insulating material (e.g., an inorganic insulating material previously exemplified).

In one embodiment, as illustrated in FIG. 3, when the first conductive layer GTL1, the second conductive layer GTL2, the third conductive layer GTL3, and the second semiconductor layer SCL2 are disposed between the first and fifth insulating layers GI1 and GI5, after forming the first insulating layer GI1 on the first semiconductor layer SCL1, the first conductive layer GTL1, the second insulating layer GI2, the second conductive layer GTL2, the third insulating layer GI3, the third conductive layer GTL3, the fourth insulating layer GI4, the second semiconductor layer SCL2, and the fifth insulating layer GI5 may be sequentially formed on the first insulating layer GI1. Each of the first, second, and third conductive layers GTL1, GTL2, and GTL3 may be formed through a conductive film formation process (e.g., a deposition process) using at least one conductive material (e.g., a conductive material previously described) and a conductive film patterning process (e.g., an etching process using a mask). The second semiconductor layer SCL2 may be formed through the semiconductor film formation process (e.g., a deposition process) using at least one semiconductor material (e.g., a semiconductor material previously described as the material of the second active layer ACT2) and a semiconductor film patterning process (e.g., an etching process using a mask).

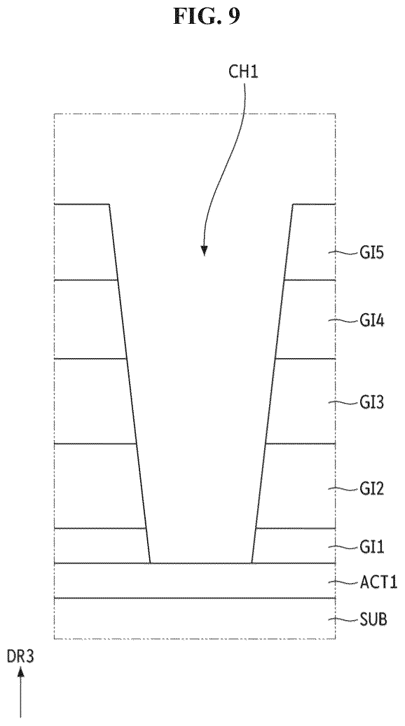

Referring to FIG. 9, the first contact hole CH1 may be formed in the insulating layers disposed on the first active layer ACT1. For example, the first contact hole CH1 may be formed by etching the first, second, third, fourth, and fifth insulating layers GI1, GI2, GI3, GI4, and GI5 in the region where the first conductive pattern CP1 is to be formed. The first contact hole CH1 may penetrate the first, second, third, fourth, and fifth insulating layers GI1, GI2, GI3, GI4, and GI5 to expose a portion of the first active layer ACT1. In the step of forming the first contact hole CH1, the second, third, and fourth contact holes CH2, CH3, and CH4 of FIG. 3 may also be formed. The second contact hole CH2 may be formed to penetrate the first, second, third, fourth, and fifth insulating layers GI1, GI2, GI3, GI4, and GI5 to expose another portion of the first active layer ACT1. The third contact hole CH3 may be formed to penetrate the second, third, fourth, and fifth insulating layers GI2, GI3, GI4, and GI5 to expose a portion of the first gate electrode GE1. The fourth contact hole CH4 may be formed to penetrate the third, fourth, and fifth insulating layers GI3, GI4, and GI5 to expose a portion of the first capacitor electrode CPE1.

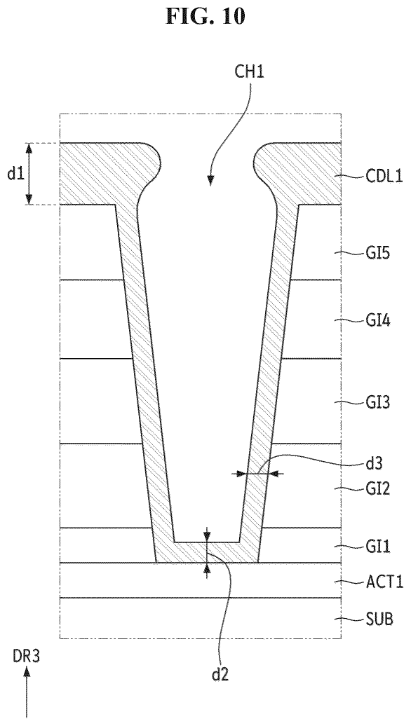

Referring to FIG. 10, the first conductive film CDL1 may be formed on the insulating layers on the first active layer ACT1 and on the first contact hole CH1. For example, the first conductive film CDL1 may be formed by depositing a conductive material on the first insulating layer GI1, the second insulating layer GI2, the third insulating layer GI3, the fourth insulating layer GI4, the fifth insulating layer GI5, and the first contact hole CH1 (or on the fifth insulating layer GI5 and the first contact hole CH1). In one embodiment, the conductive material (e.g., a metal) used to form the first conductive pattern CP1 may be deposited across the entire surface of the insulating layers on the first active layer ACT1 and on the first contact hole CH1 through sputtering, thereby forming the first conductive film CDL1. As a result, the first conductive film CDL1 can be formed easily or appropriately.

During the formation of the first conductive film CDL1, excessive accumulation of conductive material may occur near the entrance of the first contact hole CH1. As a result, the first conductive film CDL1 may form an overhang-shaped protrusion at the entrance of the first contact hole CH1. Due to the shadowing effect caused by this protrusion, the conductive material may not be uniformly deposited inside the first contact hole CH1, leading to the formation of an undercut-shaped recess beneath the protrusion. For example, the first conductive film CDL1 may be formed with a first thickness dl on the fifth insulating layer GI5, and with smaller second and third thicknesses d2 and d3 on the bottom surface and side surface, respectively, of the first contact hole CH1. The amount and form of the conductive material deposited inside the first contact hole CH1 may vary depending on the deposition conditions of the first conductive film CDL1, the size or shape of the first contact hole CH1, and other factors.

In one embodiment, if the first contact hole CH1 penetrates at least two conductive layers and has a relatively large aspect ratio (e.g., 0.3 or greater, or 0.6 or greater), there may be a significant difference in the thickness of the first conductive film CDL1 inside and outside the first contact hole CH1. For example, the second and third thicknesses d2 and d3 may each be less than half of the first thickness d1. In one embodiment, when the aspect ratio of the first contact hole CH1 is approximately 1, the second thickness d2 of the first conductive film CDL1 on the bottom surface of the first contact hole CH1 may be as small as approximately 10% to less than 15% of the first thickness d1 of the first conductive film CDL1 on the fifth insulating layer GI5. For example, at or below half the depth D of the first contact hole CH1, the second and third thicknesses d2 and d3 of the first conductive film CDL1 may be as small as approximately 11% of the first thickness d1 of the first conductive film CDL1 on the fifth insulating layer GI5. FIG. 10 illustrates the first conductive film CDL1 as being deposited with a uniform thickness on the side surface of the first contact hole CH1, but the present disclosure is not limited thereto. For example, as the deposition depth of the first conductive film CDL1 increases, the thickness of the first conductive film CDL1 deposited on the side surface of the first contact hole CH1 may decrease.

If the first conductive pattern CP1 is formed using only the first conductive film CDL1 deposited in a single iteration, the first conductive film CDL1 may not achieve sufficient thickness inside a contact hole with a large aspect ratio, such as the first contact hole CH1. For example, the second thickness d2 of the first conductive film CDL1 on the bottom surface of the first contact hole CH1 with an aspect ratio of 1 may be less than 15% of the first thickness d1 of the first conductive film CDL1 on the fifth insulating layer GI5. In such cases, contact defects, such as increased contact resistance or disconnections, may occur. To address this issue, the first conductive pattern CP1 is formed by depositing the conductive material two or more times, ensuring the stability and reliability of the electrical connection provided by the first conductive pattern CP1.

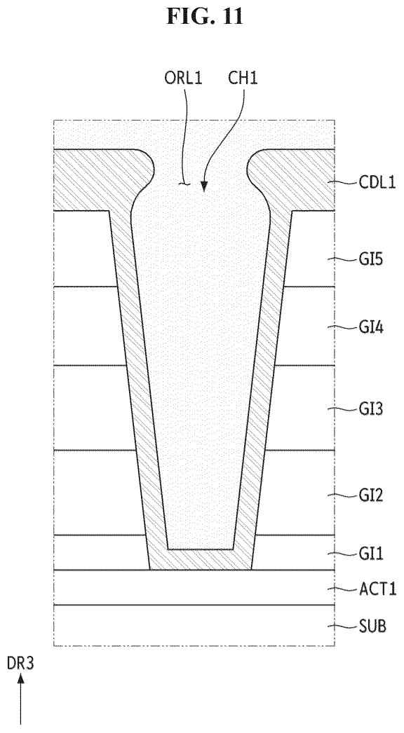

Referring to FIG. 11, the first organic film ORL1 may be formed on the first conductive film CDL1. For example, the first organic film ORL1 may be formed across the entire surface of the first conductive film CDL1 by coating the entire surface of the first conductive film CDL1 with an organic material. The organic material may also enter the first contact hole CH1. Accordingly, the first contact hole CH1 may be filled with the first organic film ORL1.

In one embodiment, the organic material may be a photoresist or a heat-resistant organic material (e.g., a POSS-based organic material, a PSPI-based organic material, a silane-based organic material, acrylic, or other heat-resistant organic materials), but the present disclosure is not limited thereto. For example, if the first organic film ORL1 is removed in subsequent processes, the heat resistance of the organic material used to form the first organic film ORL1 may not be limited.

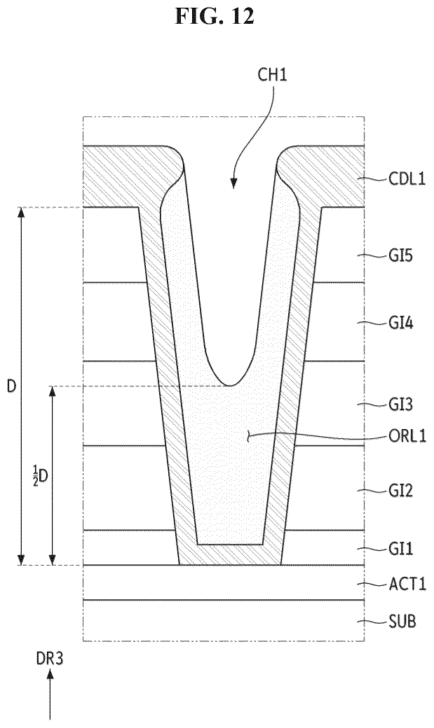

Referring to FIG. 12, a portion of the first organic film ORL1 inside the first contact hole CH1 may be remain, while the rest of the first organic film ORL1 is removed. For example, through an ashing process, a portion of the first organic film ORL1 within each contact hole (e.g., the first, second, third, and fourth contact holes CH1, CH2, CH3, and CH4 of FIG. 3), including the first contact hole CH1, may remain, while the remaining portion of the first organic film ORL1 may be removed.

In one embodiment, the ashing conditions for the first organic film ORL1 may be controlled to adjust the ashing depth of the first organic film ORL1. For example, the ashing conditions may be controlled such that the first organic film ORL1 is ashed to a depth corresponding to approximately half the depth D (e.g., 1/2D) of the first contact hole CH1.

The first organic film ORL1 may serve as a mask during a subsequent etching process of the first conductive film CDL1. The ashing depth of the first organic film ORL1 can be appropriately adjusted based on the etching depth or etching pattern of the first conductive film CDL1. Additionally, the ashing depth of the first organic film ORL1 may vary depending on the amount of conductive material deposited on the bottom and side surfaces of the first contact hole CH1.

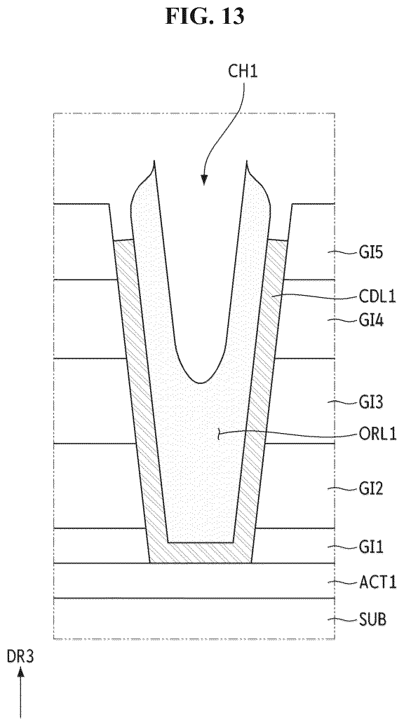

Referring to FIGS. 12 and 13, the first conductive film CDL1 may be etched using the remaining first organic film ORL1 inside the first contact hole CH1 as a mask after the ashing process. Accordingly, the portion of the first conductive film CDL1 inside the first contact hole CH1 may remain, while the rest of the first conductive film CDL1 is removed. For example, by utilizing the remaining portion of the first organic film ORL1 inside each contact hole, including the first contact hole CH1, as a mask during the etching of the first conductive film CDL1, the portion of the first conductive film CDL1 inside each contact hole can remain intact, while the rest of the first conductive film CDL1 is removed. According to this embodiment, by using the first organic film ORL1 as a mask without requiring an additional masking process, the manufacturing process of the display device 10 can be simplified, thereby reducing the manufacturing cost of the display device 10.

In one embodiment, the first conductive film CDL1 may be etched to a height less than or equal to the height of the first contact hole CH1, and the protrusion of the first conductive film CDL1 formed at the entrance of the first contact hole CH1 may also be removed. As a result, the undercut of the first conductive pattern CP1, including the etched first conductive film CDL1, can be reduced, and the amount of conductive material deposited in subsequent processes inside the first contact hole CH1 can be increased, thereby enhancing the uniformity of deposition. Similarly, in the second, third, and fourth contact holes CH2, CH3, and CH4 of FIG. 3, the first conductive film CDL1 may be etched to a height less than or equal to the height of the second, third, and fourth contact holes CH2, CH3, and CH4, and the protrusions of the first conductive film CDL1 at the entrances of the second, third, and fourth contact holes CH2, CH3, and CH4 may be removed accordingly.

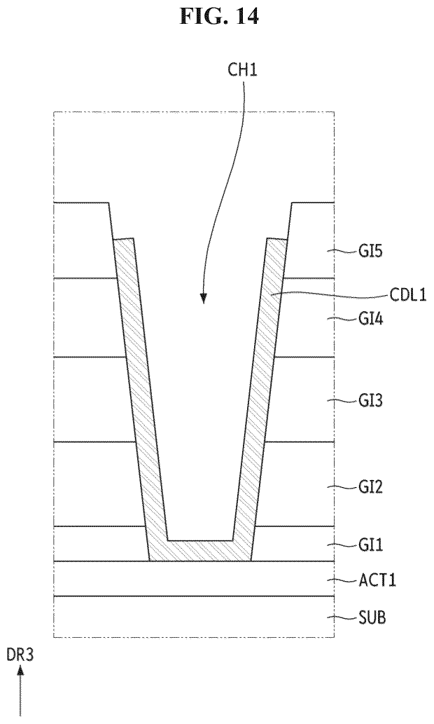

Referring to FIGS. 13 and 14, the remaining portion of the first organic film ORL1 inside the first contact hole CH1 may be removed. For example, the remaining first organic film ORL1 inside each contact hole, including the first contact hole CH1, may be removed through a stripping process.

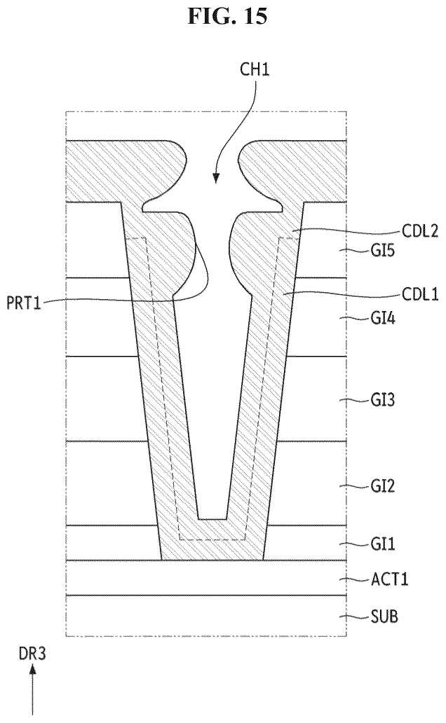

Referring to FIG. 15, a second conductive film CDL2 may be formed on the insulating layers where each contact hole, such as the first contact hole CH1, is formed, as well as on the first conductive film CDL1 within each contact hole. For example, the second conductive film CDL2 may be formed by depositing conductive material on the first insulating layer GI1, the second insulating layer GI2, the third insulating layer GI3, the fourth insulating layer GI4, the fifth insulating layer GI5, and the first conductive film CDL1 (or on the fifth insulating layer GI5 and the first conductive film CDL1). In one embodiment, the conductive material (e.g., metal) used to form the first conductive pattern CP1 may be deposited across the entire surface through sputtering, resulting in the formation of the second conductive film CDL2. This method ensures that the second conductive film CDL2 is formed efficiently and with precision.

During the formation of the second conductive film CDL2, excessive accumulation of conductive material may occur at the entrances of contact holes, including the first contact hole CH1. As a result, the second conductive film CDL2 may form overhang-shaped protrusions at these entrances. Additionally, since the first conductive film CDL1 is already present inside each contact hole, the second conductive film CDL2 may also form overhang-shaped protrusions around the upper edges of the first conductive film CDL1, such as the first protrusion PRT1 within the first contact hole CH1.

When the first conductive pattern CP1 is formed by depositing conductive material two or more times, the deposition depth of the material may be reduced due to the previously formed conductive film (e.g., the first conductive film CDL1). This can help mitigate or reduce the formation of overhangs around the entrances of contact holes. As a result, more conductive material can be deposited inside each contact hole, improving deposition quality. This enables the formation of a thicker first conductive pattern CP1 within each contact hole, covering both the bottom and side surfaces. The increased thickness enhances the stability of the electrical connection provided by the first conductive pattern CP1. In this embodiment, after etching the protrusion of the previously deposited conductive film (e.g., the first conductive film CDL1) to reduce the undercut, additional conductive material is deposited into each contact hole. This further increases the amount of deposited material and improves deposition quality. Consequently, the thickness of the conductive film on the bottom and side surfaces of each contact hole can be effectively increased, while the step coverage of the conductive film is improved.

In one embodiment, when the conductive material has been sufficiently deposited inside each contact hole through the first and second conductive films CDL1 and CDL2, forming a conductive film with a desired shape and/or thickness, the second conductive film CDL2 may be etched to form the first conductive pattern CP1. For example, the second conductive film CDL2 may be etched to match the patterns of the fourth conductive layer GTL4 in FIG. 3. As a result, the patterns of the fourth conductive layer GTL4, including the first conductive pattern CP1, can be formed.

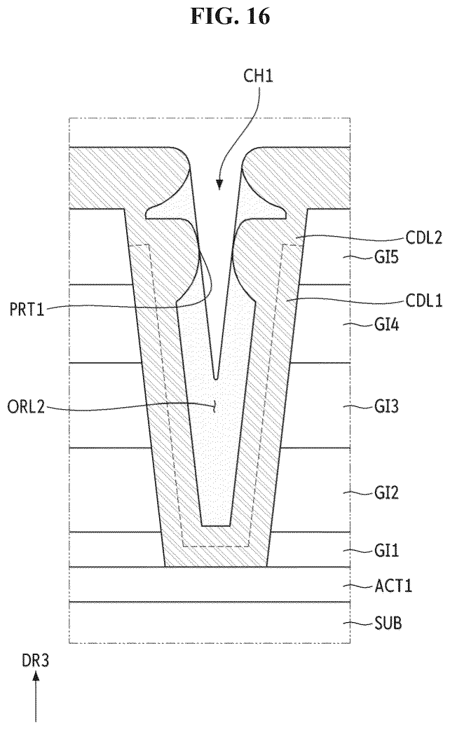

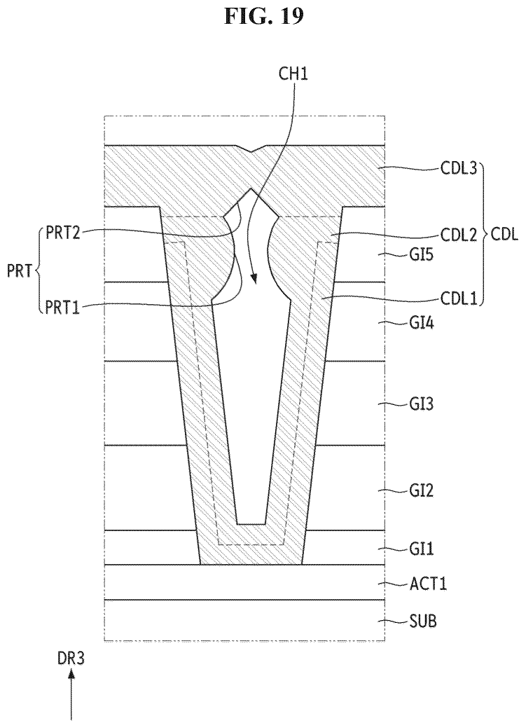

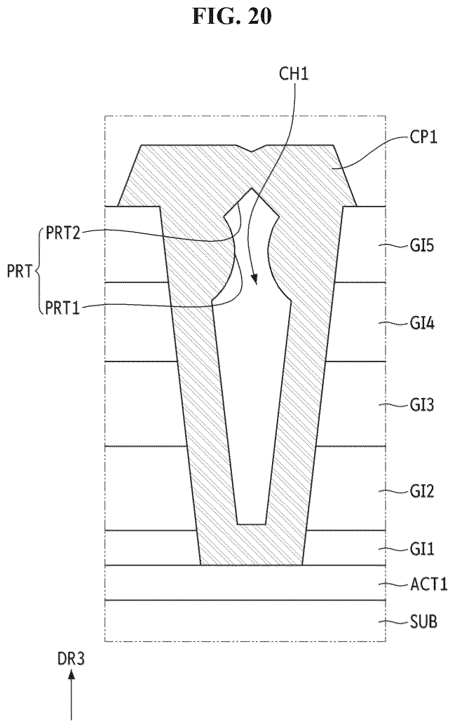

In one embodiment, if a conductive material needs to be additionally deposited inside each contact hole, as illustrated in FIGS. 16 through 18, a second organic film ORL2 may be formed inside each contact hole, and the second organic film ORL2 may be used as a mask to etch the second conductive film CDL2. Furthermore, as illustrated in FIG. 19, at least one conductive film (e.g., a third conductive film CDL3) may be additionally formed on the etched second conductive film, and as illustrated in FIG. 20, the at least one conductive film may be etched to form the first conductive pattern CP1.

Referring to FIG. 16, a second organic film ORL2 may be formed inside each contact hole, including the first contact hole CH1. For example, after coating the second conductive film CDL2 with a photoresist or other organic material, as in the process of forming the first organic film ORL1, an ashing process may be performed. As a result, the second organic film ORL2 may be formed on a portion of the second conductive film CDL2 inside each contact hole. In one embodiment, if an organic layer ORL is formed using the second organic film ORL2, as performed in the embodiment of FIG. 6, instead of removing the second organic film ORL2, a heat-resistant organic material capable of withstanding the temperatures of subsequent processes may be used to form the second organic film ORL2.

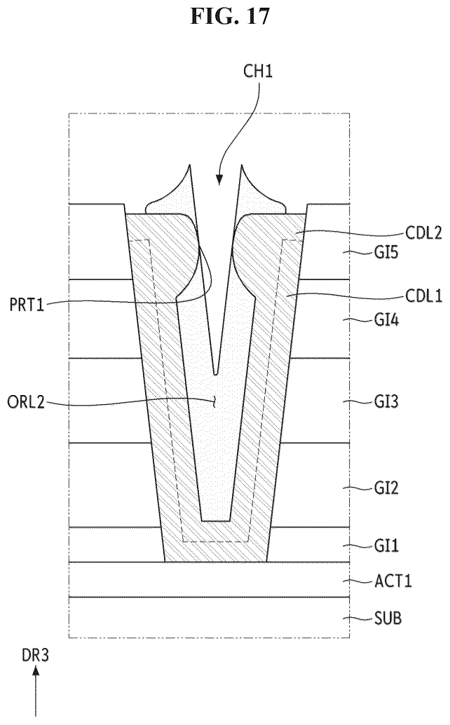

Referring to FIGS. 16 and 17, the second conductive film CDL2 may be etched using the second organic film ORL2 as a mask. Accordingly, a portion of the second conductive film CDL2 inside each contact hole, including the first contact hole CH1, may be retained, and while the remaining portion of the second conductive film CDL2 may be removed. In one embodiment, the second conductive film CDL2 may have a height less than or equal to the height of each contact hole.

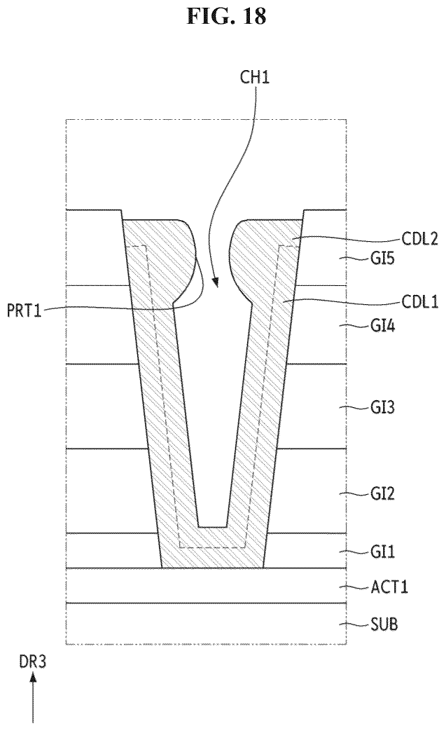

Referring to FIGS. 17 and 18, the second organic film ORL2 may be removed. For example, the second organic film ORL2 inside each contact hole may be removed through a stripping process.

In one embodiment, if the interior of each contact hole is to be filled with an organic layer ORL, as shown in the embodiment of FIG. 6, the step of removing the organic film (e.g., the second organic film ORL2 in FIG. 17) formed prior to the deposition of at least one conductive film (e.g., the third conductive film CDL3 in FIG. 19, which is the final conductive film in the process of forming each conductive pattern) may be omitted. For example, an additional conductive film may be deposited on the existing organic film without removing it. Alternatively, the organic film used as a mask may be removed, and the organic layer ORL may be formed inside each contact hole using an additional organic material (e.g., a heat-resistant organic material). Subsequently, an additional conductive film may be deposited on the organic layer ORL.

Referring to FIG. 19, a third conductive film CDL3 may be formed on the insulating layers that include the areas where each contact hole, such as the first contact hole CH1, is formed, as well as on the second conductive film CDL2 within each contact hole. For example, the third conductive film CDL3 may be formed by depositing conductive material on the first insulating layer GI1, the second insulating layer GI2, the third insulating layer GI3, the fourth insulating layer GI4, the fifth insulating layer GI5, and the second conductive film CDL2 (or on the fifth insulating layer GI5 and the second conductive film CDL2). In one embodiment, the conductive material (e.g., metal) used to form the first conductive pattern CP1 may be deposited across the entire surface using a sputtering method, thereby forming the third conductive film CDL3. As a result, the third conductive film CDL3 can be easily or appropriately formed.

During the formation of the third conductive film CDL3, excessive accumulation of conductive material may occur at the entrances of the contact holes, including the first contact hole CH1. Accordingly, the third conductive film CDL3 may form overhang-shaped protrusions PRT at the entrances of the contact holes. For example, the third conductive film CDL3 may include a second protrusion PRT2 that blocks the entrance of the first contact hole CH1. The second protrusion PRT2 may be positioned at a height greater than the height of the first protrusion PRT1. The first, second, and third conductive films CDL1, CDL2, and CDL3 formed sequentially may constitute a conductive film CDL used to form the patterns of the fourth conductive layer GTL4, including the first conductive pattern CP1.

Referring to FIGS. 19 and 20, the conductive film CDL may be etched to form the first conductive pattern CP1. For example, by etching the conductive film CDL to correspond to the patterns of the fourth conductive layer GTL4 in FIG. 3, the first conductive pattern CP1 and other patterns of the fourth conductive layer GTL4 may be formed.

FIGS. 8 through 20 illustrate the formation of the first conductive pattern CP1 through the deposition and etching of the conductive film CDL, involving three conductive material deposition processes. However, the present disclosure is not limited to this example. The number of deposition processes may vary or be optimized based on factors such as the desired thickness or shape of the first conductive pattern CP1 and the stability of the electrical connection it provides.

In one embodiment, conductive material may be deposited until the entrance of the first contact hole CH1 is completely blocked. Accordingly, a substantially flat first conductive pattern CP1 may be formed over the first contact hole CH1.

Through the processes described above with reference to FIGS. 8 through 20, the first semiconductor layer SCL1, the first insulating layer GI1, the first conductive layer GTL1, the second insulating layer GI2, the second conductive layer GTL2, the third insulating layer, the third conductive layer GTL3, the fourth insulating layer GI4, the second semiconductor layer SCL2, the fifth insulating layer GI5, and the fourth conductive layer GTL4 may be formed on the substrate SUB. Therefore, by forming the sixth insulating layer GI6, the fifth conductive layer SDL1, the seventh insulating layer ILD1, the sixth conductive layer SDL2, the eighth insulating layer ILD2, the seventh conductive layer SDL3, and the ninth insulating layer VIA on the fourth conductive layer GTL4 as in FIG. 3, the circuit layer CRL may be formed. The circuit layer CRL may include the via hole VH that exposes a portion of the seventh conductive pattern CP7 in each pixel region. In one embodiment, at least one of the conductive patterns (e.g., at least one of the second, third, and fourth conductive patterns CP2, CP3, and CP4) that penetrate the insulating layers formed below the fourth conductive layer GTL4 may be formed in a manner similar to the first conductive pattern CP1, but the present disclosure is not limited thereto. For example, at least one of the contact holes formed inside the circuit layer CRL may be formed through a conductive film formation process that includes at least two conductive material deposition processes and a conductive film etching process, thereby preventing contact defects and improving the reliability of the display device 10.

As in the embodiments of FIGS. 5 through 7, if the first conductive pattern CP1 includes multiple conductive patterns (e.g., the lower conductive pattern CP11 and the upper conductive pattern CP12), at least one of the multiple conductive patterns may be formed in a manner that is substantially identical or similar to the method for forming the first conductive pattern CP1 as performed in the embodiment of FIGS. 8 through 20. Additionally, as in the embodiment of FIG. 6, if the organic layer ORL is disposed inside the first conductive pattern CP1, the organic layer ORL may be formed from an organic film used as a mask during the etching of at least one conductive film in the process of forming the first conductive pattern CP1. For example, without performing the step of removing the second organic film ORL2 in FIG. 18, the third conductive film CDL3 in FIG. 19 may be formed on the second conductive film CDL2 and the second organic film ORL2. Accordingly, a display device 10 including an organic layer ORL surrounded by the first conductive pattern CP1 can be manufactured. Alternatively, the organic layer ORL may also be formed through an additional process.

Thereafter, the light-emitting element layer EDL and the encapsulation layer TFEL in FIG. 3 may be sequentially formed on the circuit layer CRL. Accordingly, the display device according to the embodiment of FIG. 3 can be manufactured.

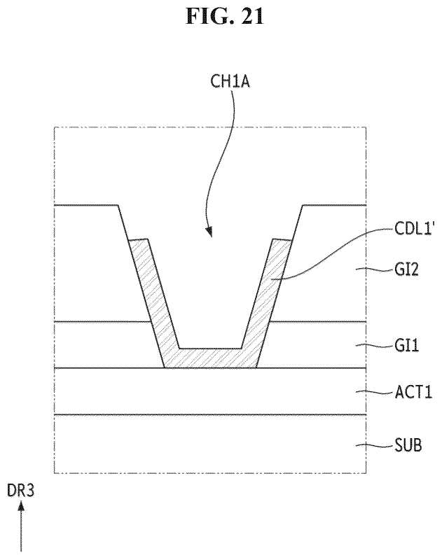

FIGS. 21 through 23 are cross-sectional views illustrating a method for manufacturing a display device according to an embodiment. For example, FIGS. 21 through 23 schematically illustrate the manufacturing steps for forming the lower conductive pattern CP11 of FIG. 5 as part of the manufacture of the display device 10 of FIGS. 1 through 3.

Referring to FIG. 21 and further to FIGS. 8 through 14, a first conductive film CDL1′ may be formed inside the lower contact hole CH1A. For example, in a manner substantially identical or similar to that described above with reference to FIGS. 8 through 10, the first insulating layer GI1, the second insulating layer GI2, and the lower contact hole CH1A may be formed on the first active layer ACT1. Subsequently, the first conductive film CDL1′ may be formed by depositing conductive material across the entire surface. Thereafter, in a manner substantially identical or similar to that described above with reference to FIGS. 11 through 14, an organic film may be formed inside the lower contact hole CH1A, and the first conductive film CDL1′ may be etched using the organic film as a mask, thereby forming the first conductive film CDL1′ inside the first contact hole CH1.

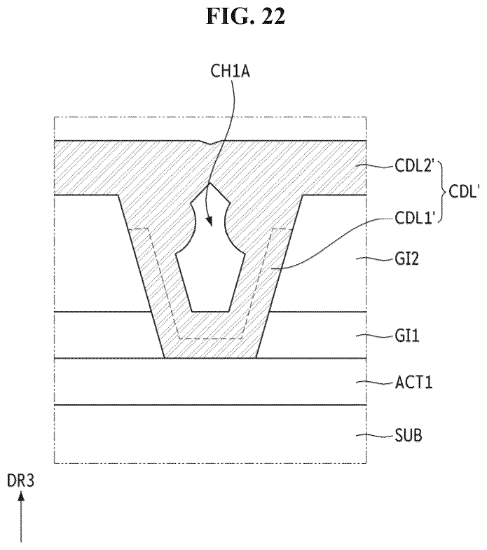

Referring to FIG. 22 and further to FIGS. 15 through 19, a second conductive film CDL2′ may be formed on the first insulating layer GI1, the second insulating layer GI2, and the first conductive film CDL1′. For example, the second conductive film CDL2′ may be formed by depositing conductive material over the entire surface of the first insulating layer GI1, the second insulating layer GI2, and the first conductive film CDL1′. In one embodiment, the conductive material may be sufficiently deposited within the lower contact hole CH1A through the first and second conductive films CDL1′ and CDL2′, forming a conductive film CDL′ with a desired shape and/or thickness. For example, depending on the size, shape, or deposition conditions of the lower contact hole CH1A, the conductive film CDL′ with an appropriate thickness and/or shape may be achieved using only two deposition processes. Additionally, if the lower contact hole CH1A penetrates a relatively small number of insulating layers and has a relatively low aspect ratio, it can be effectively filled with a minimal number of deposition processes.

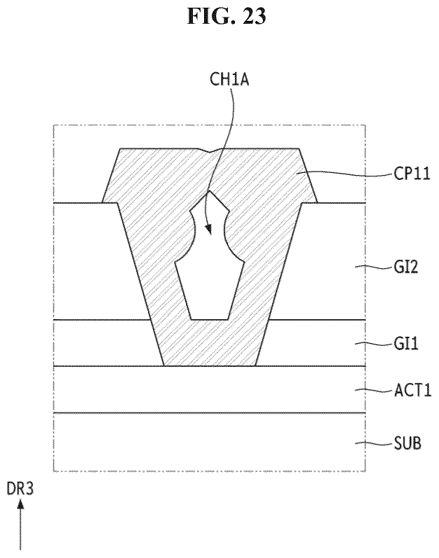

Referring to FIGS. 22 and 23, the lower conductive pattern CP11 may be formed by etching the conductive film CDL′ (e.g., the second conductive film CDL2′). For example, the lower conductive pattern CP11 may be formed by etching the conductive film CDL′ in the etching process for forming the patterns of the second conductive layer GTL2 in FIG. 3.

FIGS. 21 through 23 illustrate an embodiment where the lower conductive pattern CP11 is formed through two deposition processes, but the embodiment of FIGS. 21 through 23 is not limited to this method of forming the lower conductive pattern CP11. For example, if sufficient conductive material has been deposited inside the first contact hole CH1 during the formation of the first conductive pattern CP1 of FIGS. 3 and 4 using only two deposition processes, the first conductive pattern CP1 may then be formed by etching the conductive film formed through those two deposition processes.

In one embodiment, the organic film used for etching the first conductive film CDL1′ may not be removed, or a separate organic layer (e.g., the organic layer ORL of FIG. 6) may be formed on the first conductive film CDL1′ before forming the second conductive film CDL2′. Accordingly, the organic layer ORL may be filled inside the lower contact hole CH1A, as in the embodiment of FIG. 6.

As described above, in the disclosed embodiments, a conductive film CDL can be formed with an appropriate thickness and shape inside a contact hole that is narrow but deep. This is achieved through a conductive film formation process that includes at least two conductive film deposition processes and at least one conductive film etching process. In other words, the conductive film CDL is formed using a conductive film formation process that includes at least two deposition processes and at least one etching process. For example, in these embodiments, conductive material may be deposited with sufficient thickness inside the first contact hole CH1, which penetrates multiple insulating layers and has an aspect ratio of 0.3 or greater.

Moreover, in the disclosed embodiments, the overhang and undercut of the conductive film CDL can be improved or mitigated by appropriately etching the previously deposited conductive film CDL (e.g., the first conductive film CDL1) without the need for an additional masking process. This allows the contact hole to be effectively filled with a conductive material. For example, an organic film can be formed inside each contact hole to partially cover the conductive film CDL through a full-surface coating process followed by an ashing process. The organic film can then serve as a mask to enable the precise etching of the conductive film CDL.

According to the embodiments, a conductive film CDL with an appropriate thickness and shape can be formed inside and around each contact hole, and an appropriate conductive pattern (e.g., the first conductive pattern CP1) with a suitable thickness and shape can be formed from the conductive film CDL. For example, by etching the conductive film CDL, a conductive pattern that partially or completely fills each contact hole can be formed. The conductive pattern may have a thickness sufficient to ensure or improve the stability of electrical connections, and may be substantially flat.

A conductive pattern formed according to the embodiments may also have sufficient thickness inside each contact hole. For example, a conductive pattern filling a contact hole with an aspect ratio of 0.3 or greater may achieve a greater thickness than one formed through a single conductive material deposition process. Specifically, for a contact hole with an aspect ratio of 0.3, the thickness of the conductive pattern on the bottom surface of the contact hole may be at least 15% of the thickness at the upper part around the contact hole. If the thickness on the bottom surface of the contact hole is at least 15% of the thickness at the upper part of the contact hole, it indicates that the conductive pattern was likely formed through at least two conductive material deposition processes. In one embodiment, for a contact hole with an aspect ratio of 0.6 or greater, the number of conductive material deposition processes may be increased to more reliably fill the contact hole. For example, the conductive pattern achieve a thickness on the bottom surface of the contact hole that is at least 50% of the thickness at another part, such as the upper part around the contact hole. This ensures stable formation of the conductive pattern and improving the stability of the electrical connection provided by the conductive pattern.

Furthermore, a conductive pattern formed according to the embodiments may have a substantially flat shape over a contact hole. Since the upper surface of the conductive pattern is substantially flat, another contact hole may be placed directly on the conductive pattern in an overlapping position. Accordingly, the integration density of the circuit layer CRL can be increased, and the design of the circuit layer CRL can be optimized.

Additionally, according to the embodiments, by depositing conductive material inside a contact hole to form a conductive pattern, the reliability of the display device 10, including the conductive pattern, can be ensured regardless of whether heat treatment is performed in subsequent processes. As in the embodiment of FIG. 6, if the contact hole is filled with an organic layer ORL, a heat-resistant organic material can be used to form the organic layer ORL. This organic layer ORL is capable of withstanding the temperatures involved in subsequent processes. Accordingly, the reliability of the display device 10, including the organic layer ORL, can be ensured.

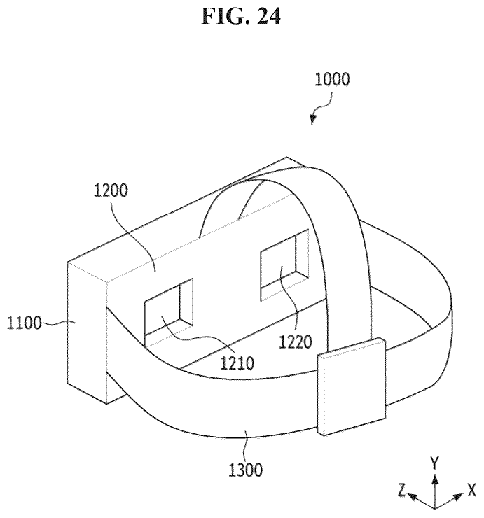

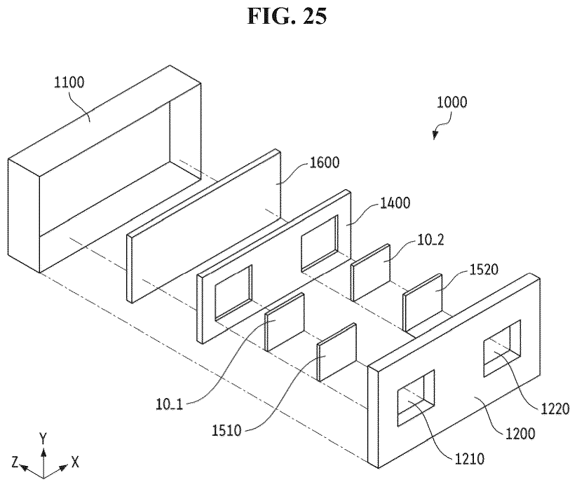

FIG. 24 is a perspective view illustrating a head-mounted display (HMD) device according to an embodiment. FIG. 25 is an exploded perspective view illustrating an example of the HMD device of FIG. 24.

Referring to FIGS. 24 and 25, an HMD device 1000 includes a first display device 10_1, a second display device 10_2, a display device housing 1100, a housing cover 1200, a first eyepiece lens 1210, a second eyepiece lens 1220, a head mounting band 1300, a middle frame 1400, a first optical member 1510, a second optical member 1520, and a control circuit board 1600.

The first display device 10_1 provides an image to a user's left eye, and the second display device 10_2 provides an image to the user's right eye. In one embodiment, the first and second display devices 10_1 and 10_2 may each correspond to the display device 10 described with reference to FIGS. 1 through 7. Thus, descriptions of the first and second display devices 10_1 and 10_2 will be omitted.

The first optical member 1510 may be disposed between the first display device 10_1 and the first eyepiece lens 1210. The second optical member 1520 may be disposed between the second display device 10_2 and the second eyepiece lens 1220. Each of the first and second optical members 1510 and 1520 may include at least one convex lens.

The middle frame 1400 may be disposed between the first display device 10_1 and the control circuit board 1600, and between the second display device 10_2 and the control circuit board 1600. The middle frame 1400 serves to support and secure the first display device 10_1, the second display device 10_2, and the control circuit board 1600.

The control circuit board 1600 may be disposed between the middle frame 1400 and the display device housing 1100. The control circuit board 1600 may be connected to the first and second display devices 10_1 and 10_2 through connectors. The control circuit board 1600 converts a video source input from the outside into digital video data DATA and transmits the digital video data DATA to the first and second display devices 10_1 and 10_2 via the connectors.

The control circuit board 1600 may transmit digital video data DATA corresponding to an image optimized for the user's left eye to the first display device 10_1 and digital video data DATA corresponding to an image optimized for the user's right eye to the second display device 10_2. Alternatively, the control circuit board 1600 may transmit the same digital video data DATA to both the first and second display devices 10_1 and 10_2.

The display device housing 1100 serves to house the first display device 10_1, the second display device 10_2, the middle frame 1400, the first optical member 1510, the second optical member 1520, and the control circuit board 1600. The housing cover 1200 is disposed to cover the open side of the display device housing 1100. The housing cover 1200 may include the first eyepiece lens 1210, disposed for the user's left eye, and the second eyepiece lens 1220, disposed for the user's right eye. FIGS. 24 and 25 illustrate the first and second eyepiece lenses 1210 and 1220 as being separately disposed, but the present disclosure is not limited thereto. The first and second eyepiece lenses 1210 and 1220 may be combined into a single unit.

The first eyepiece lens 1210 may be aligned with the first display device 10_1 and the first optical member 1510, and the second eyepiece lens 1220 may be aligned with the second display device 10_2 and the second optical member 1520. Thus, the user may view an image from the first display device 10_1, magnified as a virtual image by the first optical member 1510, through the first eyepiece lens 1210, and view the image from the second display device 10_2, also magnified as a virtual image by the second optical member 1520, through the second eyepiece lens 1220.

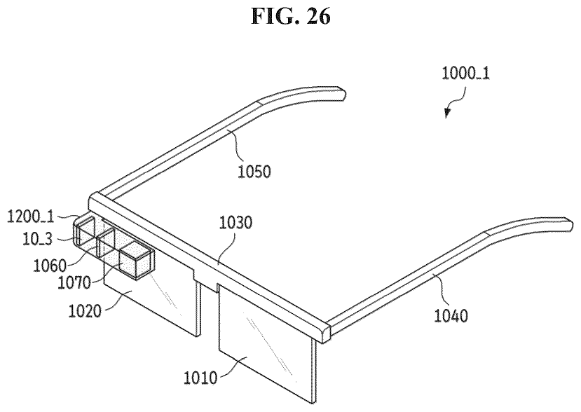

The head mounting band 1300 serves to secure the display device housing 1100 to the user's head, ensuring that the first and second eyepiece lenses 1210 and 1220 of the housing cover 1200 remain positioned in front of the user's left and right eyes, respectively. If the display device housing 1100 is designed to be lightweight and compact, the HMD device 1000 may include a pair of glasses frames, as illustrated in FIG. 26, instead of the head mounting band 1300.

In addition, the HMD device 1000 may further include a battery for supplying power, an external memory slot for storing an external memory, an external connection port, and a wireless communication module for receiving video sources. The external connection port may be a universal serial bus (USB) port, a display port, or a high-definition multimedia interface (HDMI) port, and the wireless communication module may be a 5G communication module, a 4G communication module, a Wi-Fi module, or a Bluetooth module.

FIG. 26 is a perspective view illustrating an HMD device according to another embodiment.

Referring to FIG. 26, an HMD device 1000_1 may be implemented as a glasses-type display device where a compact, lightweight display device housing 1200_1 is implemented. The HMD device 1000_1 may include a display device 10_3, a left eye lens 1010, a right eye lens 1020, a supporting frame 1030, temple arms 1040 and 1050, an optical member 1060, an optical path conversion unit 1070, and a display device housing 1200_1.

The display device housing 1200_1 may include the display device 10_3, the optical member 1060, and the optical path conversion unit 1070. In one embodiment, the display device 10_3 may correspond to the display device 10 described above with reference to FIGS. 1 through 7. An image displayed on the display device 10_3 may be magnified by the optical member 1060, and its optical path may be converted by the optical path conversion unit 1070 to be provided to a user's right eye through the right eye lens 1020. As a result, the user can view an augmented reality (AR) image in which the virtual image displayed on the display device 10_3 is combined with the real-world image seen through the right eye lens 1020.

FIG. 26 illustrates an example where the display device housing 1200_1 is disposed at the right end of the supporting frame 1030, but the present disclosure is not limited thereto. Alternatively, for example, the display device housing 1200_1 may be disposed at the left end of the supporting frame 1030, in which case, the image from the display device 10_3 may be provided to the user's left eye. Alternatively, the display device housing 1200_1 may be disposed at both the left and right ends of the supporting frame 1030, allowing the user to view the image displayed on the display device 10_3 with both eyes.

### The Electronic Device

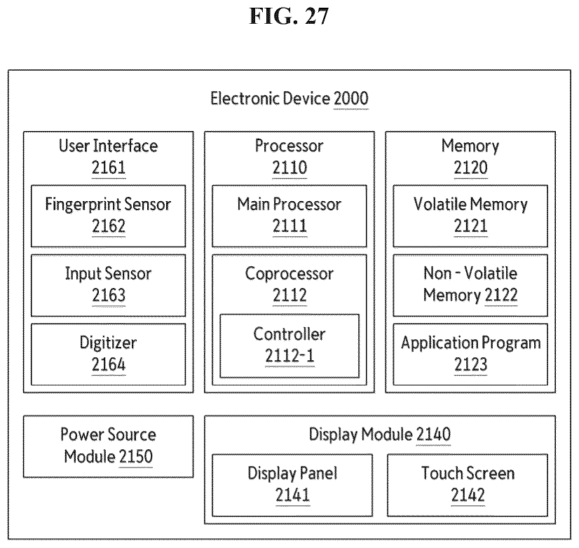

FIG. 27 is a diagram illustrating an electronic device according to an embodiment of the present invention. Referring to FIG. 27, the electronic device 2000 according to one embodiment of the present invention may output various information (e.g., images, text, music, etc.) through a display module 2140, which, for example, may correspond to the display device 10 shown in FIG. 1. When a processor 2110 executes an application stored in a memory 2120, the display module 2140 may provide application information to a user through a display panel 2141.

In some embodiments, the electronic device 2000 may be configured as a smartphone, camera, smart TV, monitor, smartwatch, tablet, automotive display, or AR/VR headset. For example, the electronic device 2000 may be a smartphone including a touch-sensitive display area DA for interaction and a non-display area NDA including sensors and circuits for enhanced functionality. For example, the electronic device 2000 may be a television or monitor including a large display area DA for high-resolution video playback and a non-display area NDA incorporating driving circuits or connectivity modules for external inputs. For example, the electronic device 2000 may be a smartwatch including a display area DA optimized for compact and high-clarity visuals and a non-display area NDA integrating biometric sensors for health monitoring. In some cases, the electronic device 2000 be an AR/VR headset.

In some embodiments, memory 2120 may store information such as software codes for operating an application program 2123. The application program 2123 may include a software designed to execute specific tasks or provide functionality to a user. The application program 2123 may operate under the control of the processor 2110 and utilizes data stored in the memory 2120 to deliver a wide range of features, such as productivity tools, multimedia streaming and playback, file or mail deliveries or communication services. The application program 2123 interacts seamlessly with the user interface 2161 or touch screen 2142, allowing a user to launch, navigate, and utilize the program through user inputs such as touch, tap, gesture, or voice interaction.

Upon user selection of an application via touch screen 2142 or user interface 2161, the processor 2110 may execute the application program 2123 corresponding to the selected application retrieved from the memory 2120 to perform functionalities of the application. For example, when a user selects a camera application by tapping the icon (or a camera application icon) presented on the display panel 2141, the processor 2110 activates a camera module. The processor 2110 may transmit image data corresponding to a captured image acquired through the camera module to the display module 2140. The display module 2140 may display an image corresponding to the captured image through the display panel 2141.

As another example, when a user wishes to make a phone call, the user taps the telephone icon displayed on the display module 2140, the processor 2110 may execute a phone application program stored in the memory 2120. A telephone keypad may be presented on the display panel 2141 for the user to enter a phone number to call.

As another example, the display module 2140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 2110 may include a main processor 2111 and an auxiliary or coprocessor 2112. The main processor 2111 may include a central processing unit (CPU). The main processor 2111 may further include one or more of a graphics processing unit (GPU), a communication processor (CP), and an image signal processor (ISP).

The coprocessor 2112 may include a controller 2112-1. The controller 2112-1 may include an interface conversion circuit and a timing control circuit. The controller 2112-1 may receive an image signal from the main processor 2111, convert the data format of the image signal to match the interface specifications with the display module 2140, and output image data. The controller 2112-1 may output various control signals to drive the display module 2140. For example, the controller 2112-1 may drive the display module 2140 to display the icon on the display screen suitable for selection by a user to cause execution of an application program 2123.

The memory 2120 may store one or more application programs 2123 and various data used by at least one component (for example, the processor 2110 or the user interface 2161) of the electronic device 2000 and input data or output data for commands related thereto. For example, a camera application program, a GPS application program, an augmented reality and virtual reality application program, and other application programs that can be executed by the processor 2110 upon selection of corresponding icons presented on the display screen (or display panel 2141) via the touch screen 2142 or user interface 2161 by the user. In addition, various setting data corresponding to user settings may be stored in the memory 2120. The memory 2120 may include volatile memory 2121 and non-volatile memory 2122.

The display module 2140 may output visual information (images) to the user. The display module 2140 may include the display panel 2141, a gate driver, the source driver, a voltage generation circuit, and a touch screen 2142. The display module 2140 may further include a window, a chassis, and a bracket to protect the display panel 2141. The display module 2140 may include at least a part of the configuration of the display device 10 shown in FIG. 1.

The user interface 2161 serves as the interaction medium between a user and the electronic device 2000. The user interface 2161 may detect an input by a part (e.g., finger) of a user's body or an input by a pen or a mouse, and generate an electric signal or data value corresponding to the input. The user interface 2161 includes the fingerprint sensor 2162, the input sensor 2163, and a digitizer 2164.

The fingerprint sensor 2162 may sense a fingerprint for biometric recognition of the user and may also measure one or more biological signals such as blood pressure, moisture, or body mass.

The input sensor 2163 may sense user interactions including touch, tap, gesture, motion, spoken command, and eye movement. The input sensor 2163 includes optical sensors for image capture, eye tracking, or motion and gesture detection. Optical sensors may be infrared or semiconductor photodetectors. The input sensor 2163 includes audio and acoustic sensors, which may be MEMS microphones for voice recognition or sound-based interaction. The audio and acoustic sensors can be installed as part of the user interface 2161 or embedded in the display panel 2141.

The digitizer 2164 may generate a data value corresponding to coordinate information of input by a pen or a mouse to control movement of an onscreen cursor. The digitizer 2164 may generate the amount of change in electromagnetic due to the input as the data value. The digitizer may detect an input by a passive pen or transmit and receive data with an active pen or a remote.

At least one of the fingerprint sensor 2162, the input sensor 2163, or the digitizer 2164 may be implemented as a sensor layer formed on the top layer of the display panel 2141 through a continuous process with a process of forming elements (for example, the light emitting element, the transistor, and the like) included in the display panel 2141.

In addition, the user interface 2161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 2142 includes touch sensors embedded in semiconductor layers of the display panel 2141 to sense pressure applied to the top layer (screen) of the display panel 2141. The touch sensors can be a capacitive or a resistive type. The touch screen 2142 may serve as the primary interface for the user to select and navigate applications, control, and interact with the electronic device 2000.

The display panel 2141 (or display) may include a liquid crystal display panel, an organic light emitting display panel, or an inorganic light emitting display panel, and the type of the display panel 2141 is not particularly limited. The display panel 2141 may be of a rigid type or a flexible type that can be rolled or folded. The display module 2140 may further include a supporter, bracket, heat dissipation member, and the like that support the display panel 2141. The display panel 2141 may include the display device 10 shown in FIG. 1.

The power source module 2150 may supply power to the components of the electronic device 2000. The power source module 2150 may include a battery that charges the power source voltage. The battery may include a non-rechargeable primary battery or a rechargeable secondary battery or fuel cell. The power source module 2150 may include a power management integrated circuit (PMIC). The PMIC may supply optimized power source to each of the components described above including the display module 2140.

In concluding the detailed description, those skilled in the art will appreciate that many variations and modifications can be made to the embodiments without substantially departing from the scope of the present invention. Therefore, the disclosed embodiments of the invention are used in a generic and descriptive sense and not for purposes of limitation.

What is claimed is:

1. A display device comprising:
a substrate;
a circuit layer disposed on the substrate and including a transistor and insulating layers; and
a light-emitting element layer disposed on the circuit layer and including a light-emitting element electrically connected to the transistor,
wherein the circuit layer includes: a contact hole penetrating at least two of the insulating layers; and a conductive pattern covering a side surface and bottom surface of the contact hole, extending upwardly beyond a top of the contact hole, and including at least two protrusions that extend toward a central axis of the contact hole in a cross-sectional view.

2. The display device of claim 1, wherein the protrusions include: a first protrusion disposed at a height less than or equal to the top of the contact hole; and a second protrusion disposed at a height greater than that of the first protrusion.

3. The display device of claim 2, wherein a thickness of the second protrusion is greater than a thickness of the first protrusion, measured along the side surface of the contact hole.

4. The display device of claim 3, wherein an upper end of the conductive pattern, including the second protrusion, completely covers an entrance of the contact hole.

5. The display device of claim 2, wherein the conductive pattern includes an undercut-shaped recess disposed between the first and second protrusions.

6. The display device of claim 2, wherein
the conductive pattern includes a third protrusion extending toward the central axis of the contact hole in a cross-sectional view, and
the first and second protrusions are disposed at a height less than or equal to the top of the contact hole.

7. The display device of claim 1, wherein the conductive pattern fills only a portion of the contact hole.

8. The display device of claim 7, wherein the contact hole includes a void surrounded by the conductive pattern.

9. The display device according to claim 7, further comprising:
an organic layer disposed inside the contact hole and filling a space surrounded by the conductive pattern.

10. The display device of claim 1, wherein
an aspect ratio of the contact hole is 0.3 or greater, and
the conductive pattern has a thickness on the bottom surface of the contact hole that is at least 15% of a thickness at an upper portion of the conductive pattern around the contact hole.

11. The display device of claim 1, wherein
an aspect ratio of the contact hole is 0.6 or greater, and
the conductive pattern has a thickness on the bottom surface of the contact hole that is at least 50% of a thickness at an upper portion of the conductive pattern around the contact hole.

12. The display device of claim 1, wherein
the contact hole includes: a lower contact hole penetrating portions of the at least two insulating layers; and an upper contact hole disposed on the lower contact hole and penetrating other portions of the at least two insulating layers, and
the conductive pattern includes: a lower conductive pattern covering a side surface and bottom surface of the lower contact hole and extending upwardly beyond a top of the lower contact hole; and an upper conductive pattern disposed on the lower conductive pattern, covering a side surface and bottom surface of the upper contact hole, and extending upwardly beyond a top of the upper contact hole.

13. The display device of claim 12, wherein at least one of the lower and upper conductive patterns includes at least two protrusions extending toward a central axis of the lower or upper contact hole in a cross-sectional view.

14. The display device of claim 1, wherein
the at least two insulating layers are disposed on an active layer of the transistor,
the contact hole penetrates the at least two insulating layers to expose a portion of the active layer, and
the conductive pattern is electrically connected to the exposed portion of the active layer.

15. A method of manufacturing a display device, comprising:
forming a pattern of a semiconductor layer or a conductive layer on a substrate covering the pattern with insulating layers;
forming a contact hole that penetrates the insulating layers to expose a portion of the pattern; and
forming a conductive pattern that fills at least a portion of the contact hole,
wherein the forming the conductive pattern includes: forming a first conductive film on the insulating layers and the contact hole; forming a first organic film on the first conductive film; retaining only a portion of the first organic film inside the contact hole and removing other portions of the first organic film; etching the first conductive film using a remaining portion of the first organic film as a mask; removing the remaining portion of the first organic film; and forming a second conductive film on the insulating layers and the first conductive film.

16. The method of claim 15, wherein the forming the first conductive film and the forming the second conductive film include depositing a conductive material over an entire surface, which includes the insulating layers and the contact hole, by sputtering.

17. The method of claim 15, wherein the forming the conductive pattern includes: forming a second organic film on a portion of the second conductive film inside the contact hole; etching the second conductive film using the second organic film as a mask; forming a third conductive film on the insulating layers and the second conductive film; and etching the third conductive film into a shape corresponding to the conductive pattern.

18. The method of claim 17, wherein the forming the conductive pattern further includes removing the second organic film before the forming the third conductive film.

19. The method of claim 17, wherein, before the forming the third conductive film, the second organic film is not removed, or a separate organic layer is formed on the second conductive film and the third conductive film is formed on the second organic film or the organic layer.

20. The method of claim 15, wherein the forming the conductive pattern further includes etching the second conductive film into a shape corresponding to the conductive pattern.
